(19) United States
(12) Patent Application Publication
(10) Pub. No.: US 2022/0327254 A1
(43) Pub. Date: Oct. 13, 2022

(54) FLOOR LAYOUT GENERATION AND UNIT LOCATION DETERMINATION

(71) Applicant: Verizon Patent and Licensing Inc., Basking Ridge, NJ (US)

(72) Inventors: Vipul Jha, Plano, TX (US); Sheikbharith Liakathali, Irving, TX (US); Rajat Sharma, Southlake, TX (US)

(21) Appl. No.: 17/226,120

(22) Filed: Apr. 9, 2021

(51) Int. Cl. G06F 30/13; G06F 30/27; G06N 20/00

(52) U.S. Cl. CPC G06F 30/13; G06F 30/27; G06N 20/00

(57) ABSTRACT

One or more computing devices, systems, and/or methods for generating floor layouts associated with buildings and/or determining locations of units are provided. In an example, a machine learning model may be trained using a plurality of sets of building information associated with a plurality of buildings to generate a trained machine learning model. A building profile associated with a building may be generated. The building profile may be indicative of geographical boundaries associated with the building and/or one or more locations associated with one or more units in the building. A unit number configuration associated with the building may be determined, using the trained machine learning model, based upon the building profile. A floor layout associated with the building may be generated based upon the unit number configuration. The floor layout may be indicative of a first arrangement of first units in the building and/or first unit numbers associated with the first units.

### BACKGROUND

A floor plan of a building may be used for one or more tasks, such as determining a location of a unit in a building, network coverage, or the like. However, there are many buildings that do not have publicly available floor plans or the floor plans are not easily ascertainable. Further, floor plans may be expensive to obtain and thus may prevent knowledge of building layout used in network planning or the like.

### BRIEF DESCRIPTION OF THE DRAWINGS

While the techniques presented herein may be embodied in alternative forms, the particular embodiments illustrated in the drawings are only a few examples that are supplemental of the description provided herein. These embodiments are not to be interpreted in a limiting manner, such as limiting the claims appended hereto.

FIG. 1A is a diagram illustrating an example system for generating floor layouts associated with buildings and/or determining locations of units, where locations are received by a floor layout system according to some embodiments.

FIG. 1B is a diagram illustrating unit location data, of an example system for generating floor layouts associated with buildings and/or determining locations of units, according to some embodiments.

FIG. 1C is a diagram illustrating an example system for generating floor layouts associated with buildings and/or determining locations of units, where a machine learning training module trains a machine learning model to generate a machine learning model according to some embodiments.

FIG. 1D is a diagram illustrating exemplary sets of building sections associated with buildings, of an example system for generating floor layouts associated with buildings and/or determining locations of units, according to some embodiments.

FIG. 1E is a diagram illustrating exemplary unit layouts associated with unit layout classifications, of an example system for generating floor layouts associated with buildings and/or determining locations of units, according to some embodiments.

FIG. 1F is a diagram illustrating an example of a polygon and/or one or more unit locations, of an example system for generating floor layouts associated with buildings and/or determining locations of units, according to some embodiments.

FIG. 1G is a diagram illustrating an example system for generating floor layouts associated with buildings and/or determining locations of units, where floor layout information is determined using a machine learning model according to some embodiments.

FIG. 1H is a diagram illustrating an example system for generating floor layouts associated with buildings and/or determining locations of units, where a floor layout is determined based upon floor layout information according to some embodiments.

FIG. 1I is a diagram illustrating an example system for generating floor layouts associated with buildings and/or determining locations of units, where a request for a service is received by a floor layout system from a client device according to some embodiments.

FIG. 1J is a diagram illustrating an example system for generating floor layouts associated with buildings and/or determining locations of units, where a unit location of a unit is determined according to some embodiments.

FIG. 2 is a flow chart illustrating an example method for generating floor layouts associated with buildings and/or determining locations of units according to some embodiments.

FIG. 3 is an illustration of a scenario involving various examples of transmission mediums that may be used to communicatively couple computers and clients.

FIG. 4 is an illustration of a scenario involving an example configuration of a computer that may utilize and/or implement at least a portion of the techniques presented herein.

FIG. 5 is an illustration of a scenario involving an example configuration of a client that may utilize and/or implement at least a portion of the techniques presented herein.

FIG. 6 is an illustration of an example environment in which at least a portion of the techniques presented herein may be utilized and/or implemented.

FIG. 7 is an illustration of an example network that may utilize and/or implement at least a portion of the techniques presented herein.

FIG. 8 is an illustration of a scenario featuring an example non-transitory machine readable medium in accordance with one or more of the provisions set forth herein.

### DETAILED DESCRIPTION OF EXAMPLE EMBODIMENTS

Subject matter will now be described more fully hereinafter with reference to the accompanying drawings, which form a part hereof, and which show, by way of illustration, specific example embodiments. This description is not intended as an extensive or detailed discussion of known concepts. Details that are well known may have been omitted, or may be handled in summary fashion.

The following subject matter may be embodied in a variety of different forms, such as methods, devices, components, and/or systems. Accordingly, this subject matter is not intended to be construed as limited to any example embodiments set forth herein. Rather, example embodiments are provided merely to be illustrative. Such embodiments may, for example, take the form of hardware, software, firmware or any combination thereof.

The following provides a discussion of some types of computing scenarios in which the disclosed subject matter may be utilized and/or implemented.

One or more systems and/or techniques for generating floor layouts associated with buildings and/or determining locations of units are provided. In some examples, a location of a unit of a building may be used for providing one or more services, such as at least one of a delivery service, determining whether the unit is within coverage of a service (e.g., at least one of internet service, cellular service, etc.), etc. In some systems, the location of the unit may be determined based upon floor layouts of buildings that are at least one of received from a floor layout provider system (e.g., a system of a floor layout provider, where the floor layout provider may receive compensation for providing the floor layouts), determined by physically surveying the buildings, etc. Thus, determining location of units in these systems may require high costs and/or a high level of manual effort. Further, these systems may not be used to determine locations of units that are in buildings for which floor layouts are not provided by a floor layout provider and/or buildings that have not been physically surveyed.

Accordingly, as provided herein, a machine learning model may be trained using a plurality of sets of building information to generate a machine learning model. In an example, the plurality of sets of building information may be received from a floor layout provider system and/or may be determined by physically surveying buildings associated with the plurality of sets of building information. In some examples, a set of building information of the plurality of sets of building information may be indicative of at least one of unit layout information associated with a building, a building shape associated with the building, etc. The trained machine learning model may be trained and/or configured to determine one or more characteristics (e.g., floor layout information) associated with a building based upon a building profile.

In some examples, a building profile associated with a building may be generated. The building profile may be generated based upon one or more known unit locations of the building. For example, the one or more known unit locations may comprise one or more locations of one or more units of the building. The one or more known unit locations may be received from one or more devices (e.g., at least one of one or more client devices associated with one or more users and/or customers, one or more engagement management devices, one or more technician devices, etc.). The one or more known unit locations may be received during and/or in conjunction with performance of a service, such as at least one of a delivery service, determining whether the unit is within coverage of a service (e.g., at least one of internet service, cellular service, etc.), etc. The one or more known unit locations may comprise merely a portion of unit locations of the building.

In some examples, a unit number configuration and/or building shape information associated with the building may be determined, using the trained machine learning model, based upon the building profile associated with the building. A first floor layout associated with the building may be generated based upon the unit number configuration and/or the building shape information. The first floor layout may be indicative of an arrangement of units in the building and/or unit numbers associated with the units. For example, the arrangement of units may be indicative of unit locations of the units. The unit locations of the arrangement of units may comprise one or more unit locations that are not comprised in the one or more known unit locations (e.g., the one or more unit locations may be extrapolated from the one or more known unit locations using the trained machine learning model).

In some examples, a unit number of a unit in the building may be received. A location of the unit may be determined based upon the first floor layout. By using one or more of the techniques herein (e.g., by using the trained machine learning model to determine the unit number configuration and/or the building shape information, and/or by generating the floor layout based upon the unit number configuration and/or the building shape information), the first floor layout and/or the location may be determined automatically with increased speed, with less cost and/or with less manual effort than other systems.

In some examples, the location of the unit may be used to determine whether the unit is within coverage of a service (e.g., at least one of internet service, cellular service, etc.). Thus, by using one or more of the techniques herein, determining whether the unit is within coverage of the service may be performed automatically with increased speed, with less cost and/or with less manual effort than other systems.

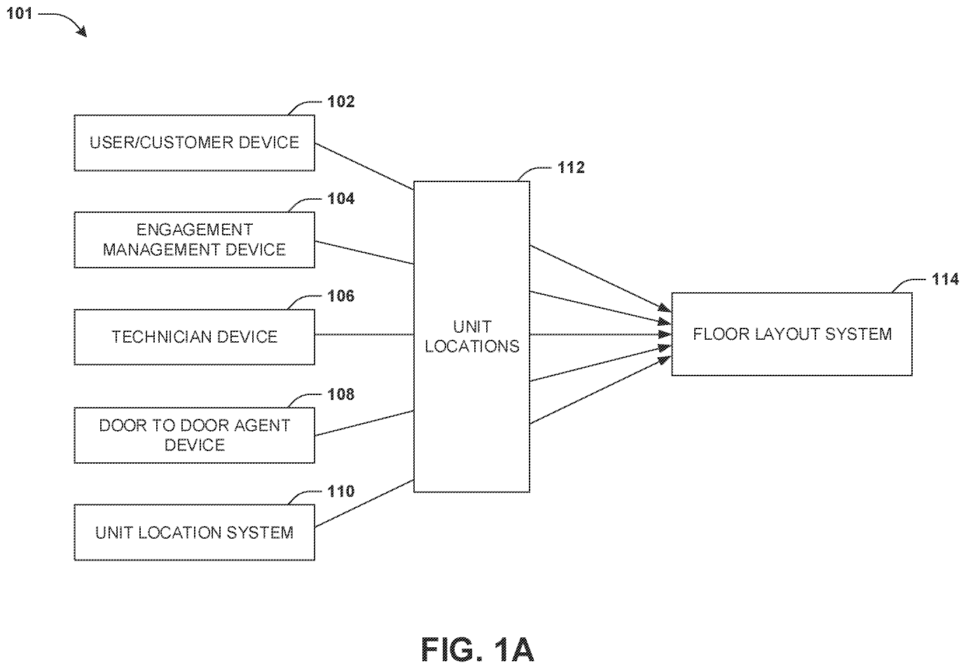

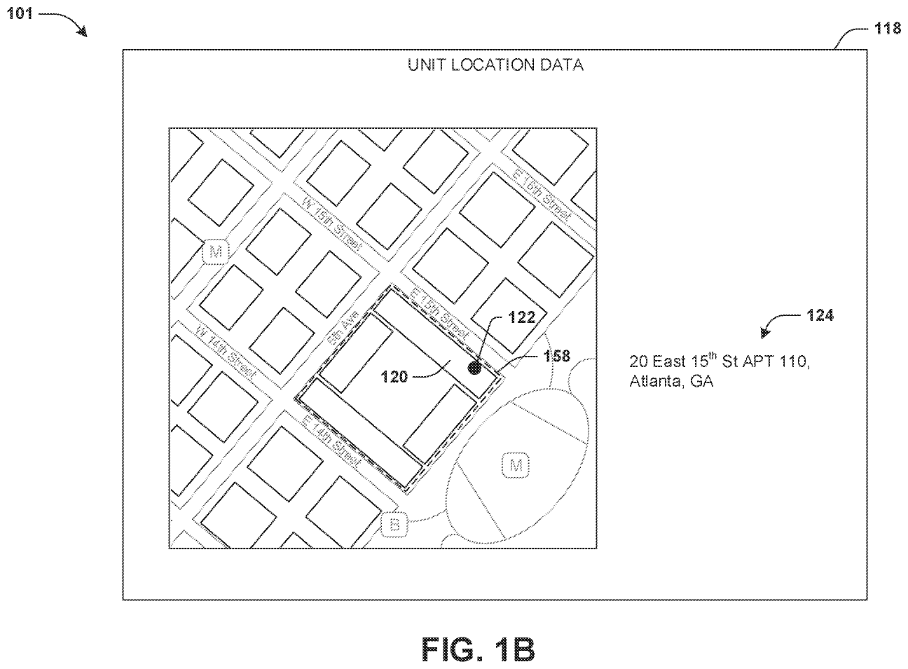

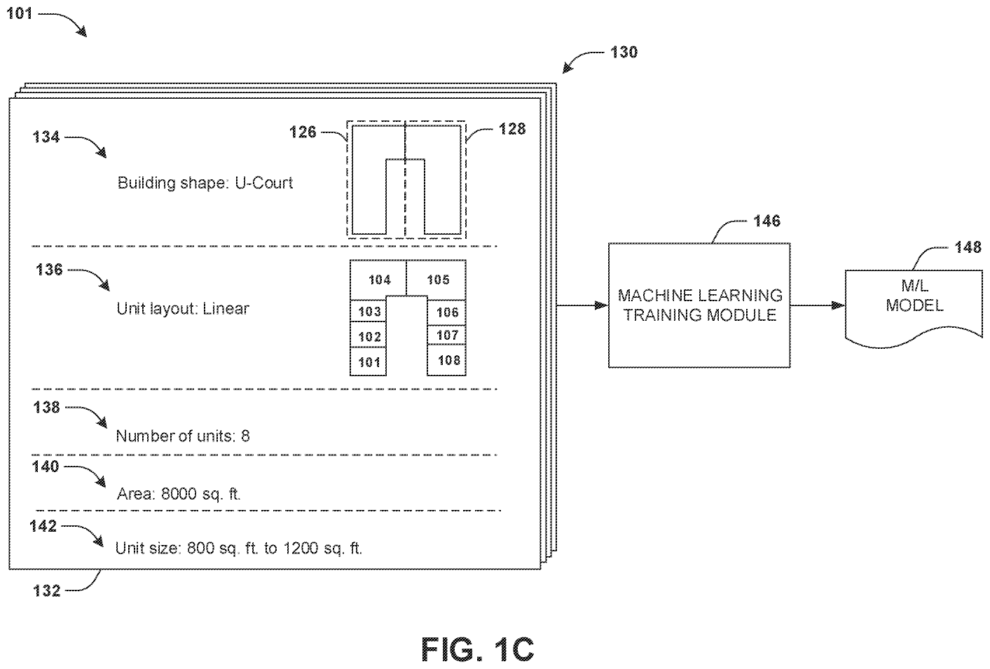

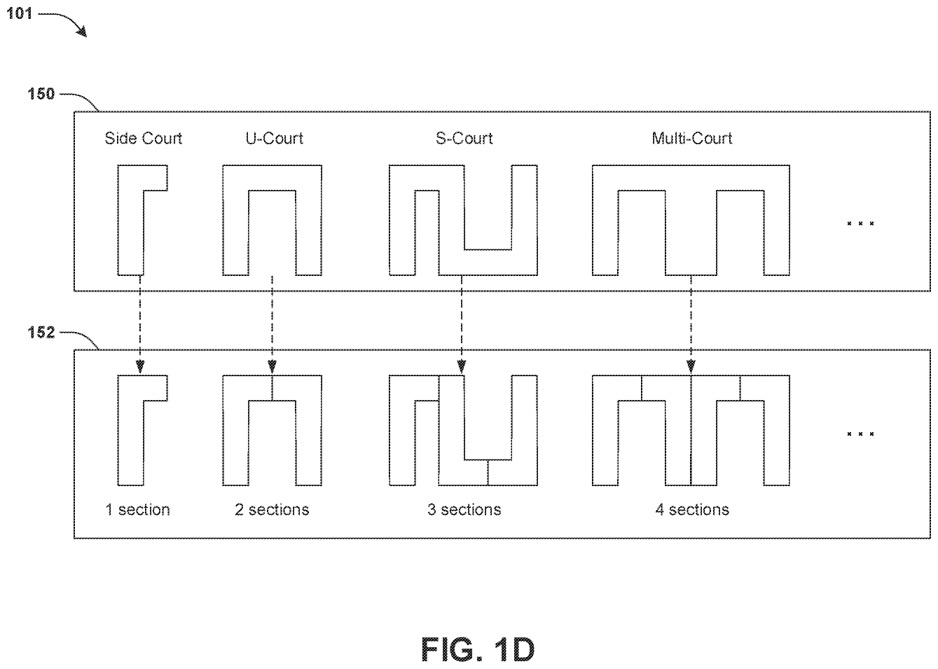

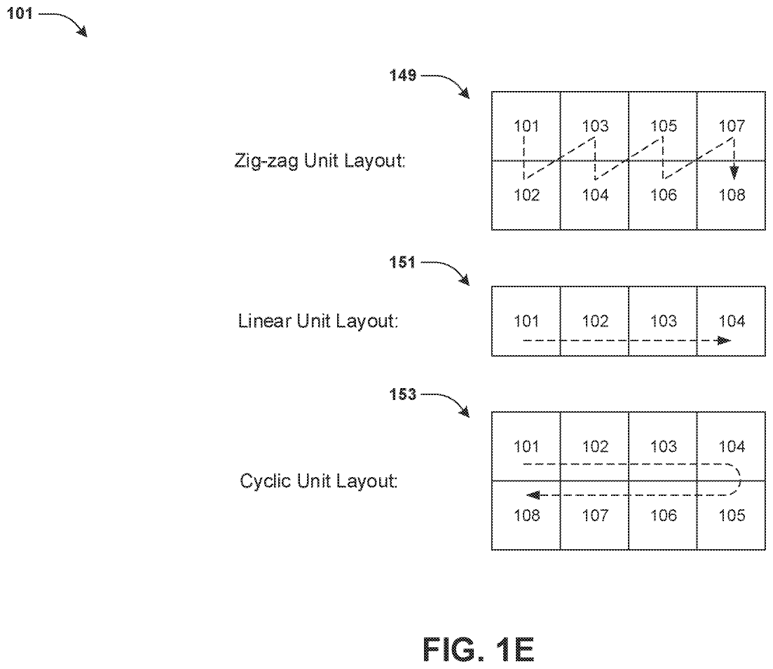

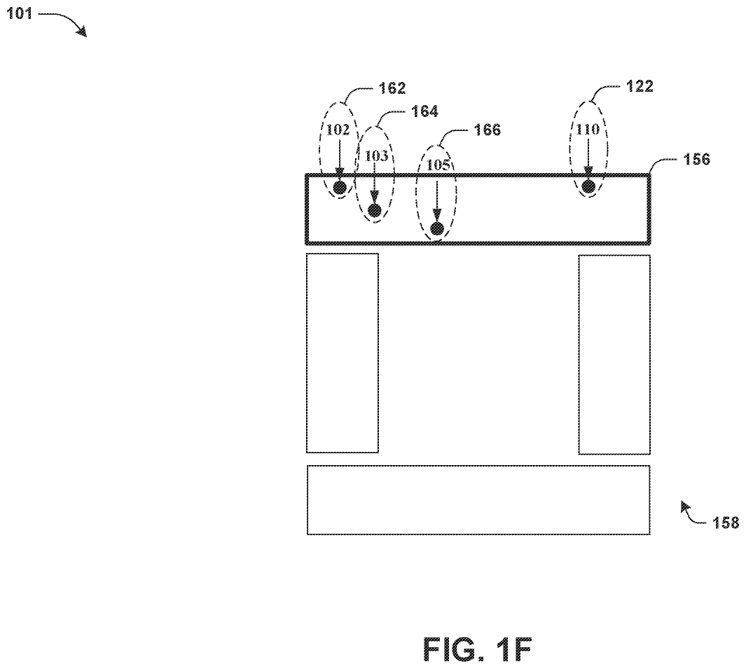

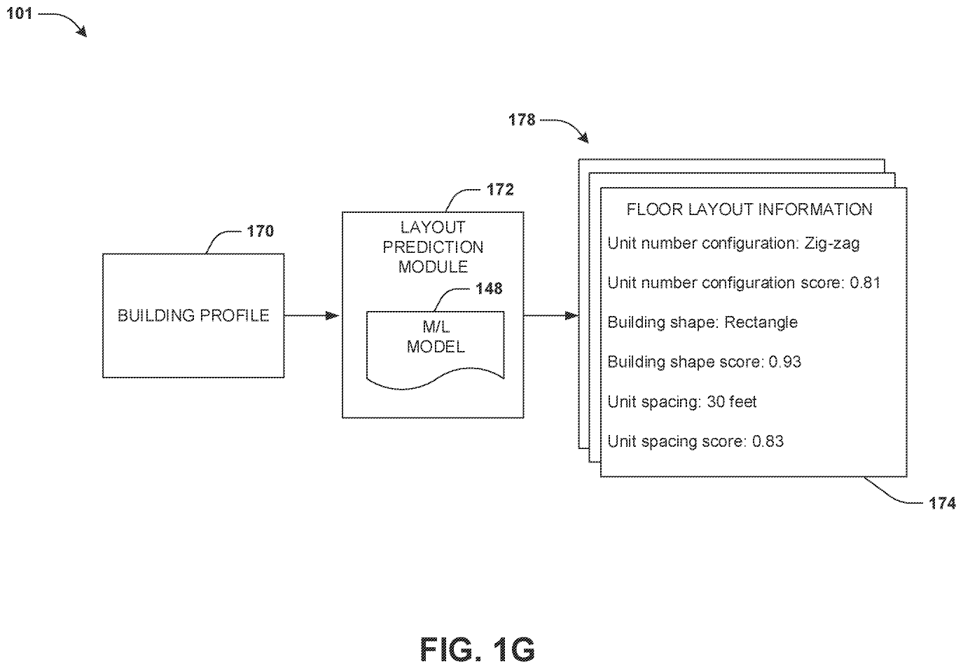

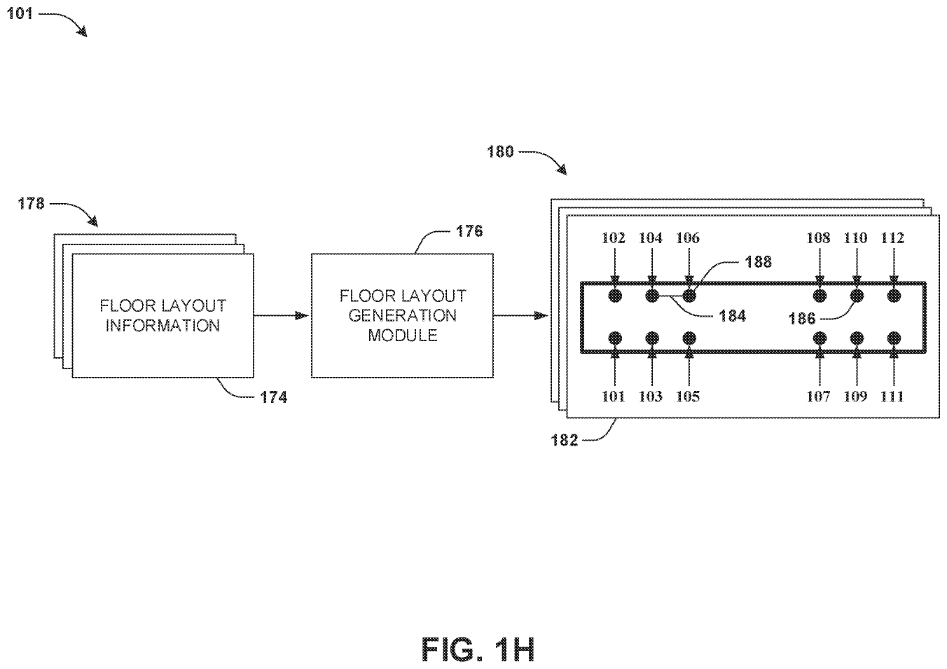

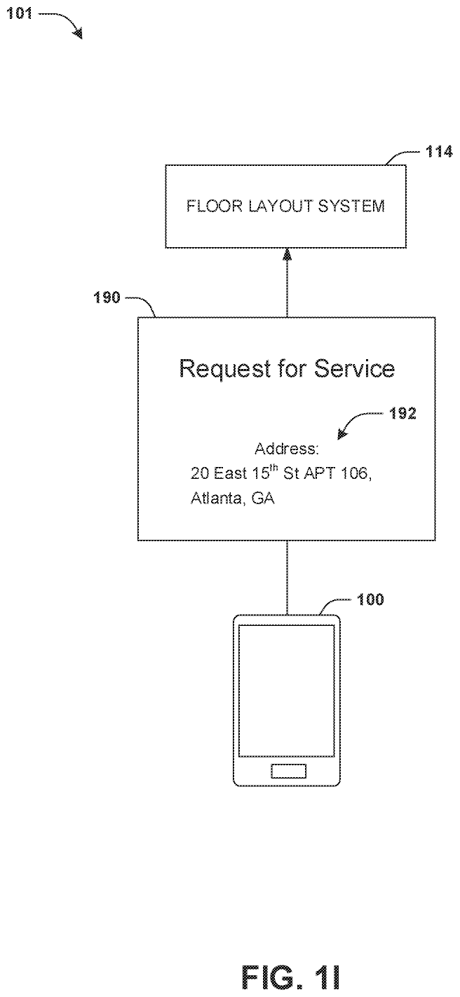

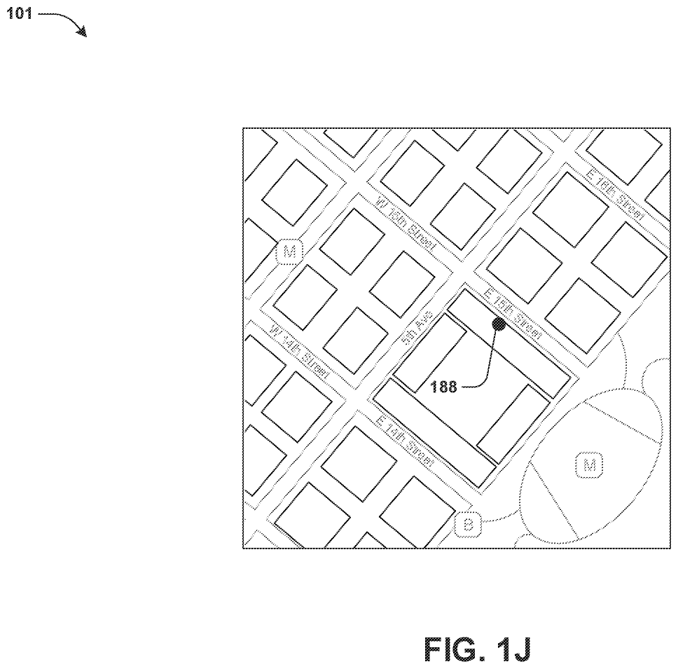

FIGS. 1A-1J illustrate examples of a system 101 for generating floor layouts associated with buildings and/or determining locations of units. In some examples, the term “building” used herein may correspond to at least one of a structure, an apartment building, an apartment complex, a shopping complex, a school, a factory, a residential area, a shopping center, a set of condominiums and/or townhouses, a single building, multiple buildings (such as multiple buildings that are connected to each other or separate from each other and/or such as multiple buildings that are part of a complex, such as at least one of a residential complex, a shopping complex, a business complex, etc.), a structure (e.g., a structure with a roof, walls and/or windows), multiple structures (e.g., multiple structures, wherein each structure of the multiple structures has a roof, walls and/or windows), etc. The building may have multiple units. A unit may correspond to at least one of a residential unit, an apartment unit, a condominium unit, a townhouse unit, a living space, an office unit (of an office building, for example), a suite, a business unit (of a shopping center with multiple units such as one or more stores, one or more restaurants and/or one or more businesses), a store (of a shopping center with multiple units such as one or more stores, one or more restaurants and/or one or more businesses), a restaurant (of a shopping center with multiple units such as one or more stores, one or more restaurants and/or one or more businesses), etc.

In some examples, a plurality of locations associated with a plurality of units (e.g., units of buildings) may be received from one or more devices and/or one or more systems. FIG. 1A illustrates the plurality of locations (shown with reference number 112 in FIG. 1A) being received by a floor layout system 114. For example, the floor layout system 114 may use the plurality of locations 112 to generate floor layouts associated with buildings. Alternatively and/or additionally, the floor layout system 114 may use the floor layouts to determine locations of units in the buildings.

In some examples, at least some of the plurality of locations 112 may be received from one or more devices 102 (e.g., client devices, such as at least one of one or more phones, one or more laptops, one or more computers, one or more wearable devices, one or more smart devices, one or more televisions, any other type of computing device, hardware, etc.) associated with one or more users. For example, a user associated with a device 102 may be a customer (and/or potential customer) of a service, such as internet service, cellular service, delivery service, etc. In an example, the user and/or the device 102 may transmit a location of a unit of a building and/or an address of the unit to the floor layout system 114. In an example where the service is internet service and/or cellular service, it may be determined, based upon the location and/or the address, whether or not the unit is within coverage of the service. In an example where the service is delivery service, one or more items (e.g., at least one of a food order, a package, one or more products, one or more goods, one or more services, etc.) may be delivered to the unit based upon the location and/or the address. In some examples, the location may correspond to a pinned location that is input (by the user, for example) via an interface (e.g., a map interface for selecting and/or sharing locations) of the device 102, such as an application programming interface (API) and/or a graphical user interface (GUI). Alternatively and/or additionally, the location may be determined using one or more global navigation satellite system (GNSS) signals received by the device 102 at a time in which the device 102 is within the unit.

In some examples, at least some of the plurality of locations 112 may be received from one or more engagement management devices 104 (associated with the service, for example). For example, an engagement management device 104 may be associated with an engagement manager tasked with assisting a customer in using the service and/or solving problems with the service (e.g., internet service, cellular service, etc.). In an example, the engagement manager and/or the engagement management device 104 may transmit a location of a unit of a building and/or an address of the unit to the floor layout system 114. For example, the engagement management device 104 may transmit the location and/or the address of the unit when the engagement manager is assisting a customer at the unit. In some examples, the location may correspond to a pinned location that is input (by the engagement manager, for example) via an interface (e.g., a map interface for selecting and/or sharing locations) of the engagement management device 104, such as an API and/or a GUI. Alternatively and/or additionally, the location may be determined using one or more GNSS signals received by the engagement management device 104 at a time in which the engagement management device 104 is at the unit. For example, it may be determined that the engagement management device 104 is at the unit based upon a determination that the engagement manager is assisting a customer at the unit.

In some examples, at least some of the plurality of locations 112 may be received from one or more technician devices 106 (associated with the service, for example). For example, a technician device 106 may be associated with a technician tasked with installing, repairing and/or inspecting one or more products associated with the service (e.g., installing and/or repairing a modem, a receiver, a router, etc. and/or determining a viability and/or usability of a product in a unit of a building, such as based upon a signal strength of a signal in the unit). In an example, the technician and/or the technician device 106 may transmit a location of a unit of a building and/or an address of the unit to the floor layout system 114. For example, the technician device 106 may transmit the location and/or the address of the unit when the technician is assisting a customer at the unit. In some examples, the location may correspond to a pinned location that is input (by the technician, for example) via an interface (e.g., a map interface for selecting and/or sharing locations) of the technician device 106, such as an API and/or a GUI. Alternatively and/or additionally, the location may be determined using one or more GNSS signals received by the technician device 106 at a time in which the technician device 106 is at the unit. For example, it may be determined that the technician device 106 is at the unit based upon a determination that the technician is installing, repairing and/or inspecting one or more products at the unit.

In some examples, at least some of the plurality of locations 112 may be received from one or more door to door agent devices 108 (associated with the service, for example). For example, a door to door agent device 108 may be associated with an agent tasked with going to various units (such as for promoting the service, for providing one or more informational materials and/or for recording locations of units of buildings). In an example, the agent and/or the agent device 108 may transmit a location of a unit of a building and/or an address of the unit to the floor layout system 114. In some examples, the location may correspond to a pinned location that is input (by the agent, for example) via an interface (e.g., a map interface for selecting and/or sharing locations) of the agent device 108, such as an API and/or a GUI. Alternatively and/or additionally, the location may be determined using one or more GNSS signals received by the agent device 108 at a time in which the agent device 108 is at the unit. For example, it may be determined that the agent device 108 is at the unit based upon a determination that the agent is promoting the service and/or providing one or more informational materials at the unit.

In some examples, at least some of the plurality of locations 112 may be received from one or more unit location systems 110. For example, a unit location system 110 may be configured to provide locations and/or addresses associated with units of buildings. In an example, the unit location system 110 may transmit one or more locations of one or more units in one or more buildings and/or one or more addresses of the one or more units, to the floor layout system 114, in response to receiving a request for unit locations and/or unit addresses (e.g., the floor layout system 114 may transmit the request to the unit location system 110).

FIG. 1B illustrates unit location data 118 associated with a unit of a first building 158. The unit location data 118 may be indicative of a first unit location 122 (of the plurality of locations 112) of the unit and/or an address 124 of the unit. The address 124 may be indicative of unit number “110” of the unit. For example, the unit number may be determined based upon the address 124 (such as using one or more of the techniques discussed herein). The first unit location 122 and/or the address 124 associated with the unit may be received from at least one of a device 102 associated with a user (e.g., a customer), an engagement management device 104, a technician device 106, a door to door agent device 108, a unit location system 110, etc.

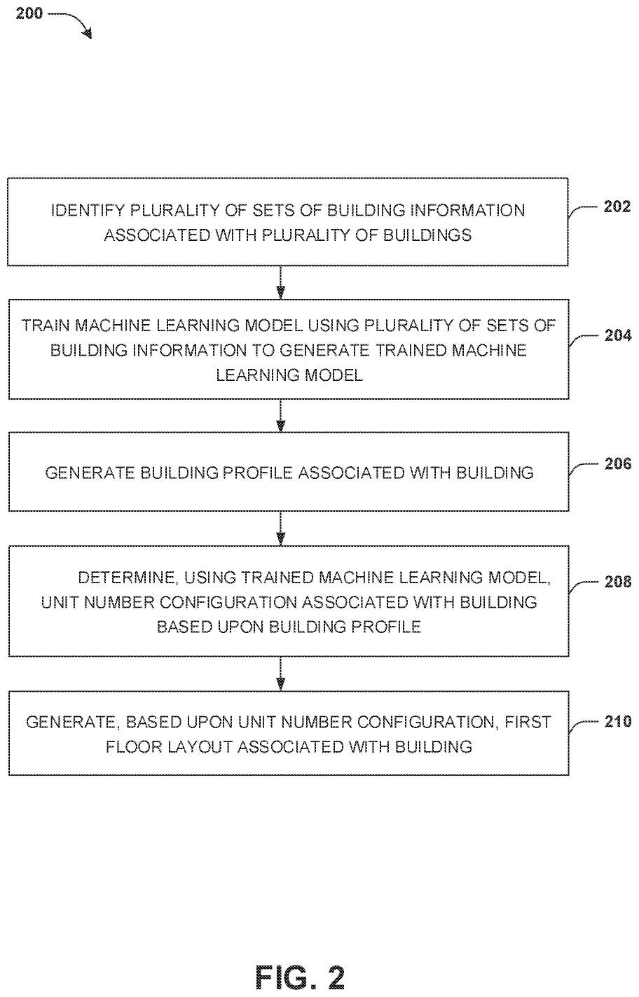

An embodiment of generating floor layouts associated with buildings and/or determining locations of units is illustrated by an exemplary method 200 of FIG. 2, and is further described in conjunction with the system 101 of FIGS. 1A-1J. At 202, a plurality of sets of building information associated with a plurality of buildings may be identified. In some examples, a set of building information of the plurality of sets of building information (and/or each set of building information of the plurality of sets of building information) is indicative of a floor layout associated with a building of the plurality of buildings and a building shape associated with the building.

At 204, a machine learning model may be trained using the plurality of sets of building information to generate a first machine learning model. FIG. 1C illustrates a training module 146 train a machine learning model to generate the first machine learning model (shown with reference number 148 in FIG. 1C). In an example, the plurality of sets of building information (shown with reference number 130 in FIG. 1C) may be input to the training module 146. The training module 146 may generate the first machine learning model 148 using the plurality of sets of building information 130.

In some examples, the plurality of sets of building information 130 comprises a first set of building information 132 associated with a second building. In some examples, the first set of building information 132 may comprise information associated with the second building (as a whole, for example) and/or sections of the second building. A section of the second building may correspond to at least one of a portion of the second building, a part of the second building, a wing of the second building, a structure of the second building, etc. In some examples, the second building may have multiple sections (e.g., the second building may be split into multiple sections).

FIG. 1D illustrates exemplary sets of building sections 152 associated with buildings having building shapes 150. For example, a side court building (e.g., L-shaped building) may have one section. Alternatively and/or additionally, a U-court building may have two sections (e.g., the two sections may comprise at least one of a set of two L-shaped sections (as shown in FIG. 1D), a set of two sections comprising a rectangular-shaped (not shown) section and an L-shaped section, etc.). Alternatively and/or additionally, an S-court building may have 3 sections. Alternatively and/or additionally, a multi-court building may have 4 sections. It may be appreciated that the sets of building sections 152 shown in FIG. 1D are merely exemplary, and a set of building sections 152 associated with a building shape 150 having other section quantities and/or other section shapes not shown in FIG. 1D is within the scope of the present disclosure. For example, a building and/or a building shape may be divided and/or split into any number of sections and/or the sections may have any shape. Alternatively and/or additionally, a building may be divided and/or split into sections based upon structures of the building (e.g., in a scenario in which a building comprises multiple structures separate from each other, such as an east wing that is separate from a west wing, the building may be divided into multiple sections wherein each section of the multiple sections corresponds to a structure of the multiple structures).

In an example shown in FIG. 1C, the second building may have a first section 126 and a second section 128. For example, the second building (having a U-court building shape, for example) may have two L-shaped sections (e.g., the first section 126 and the second section 128 as shown in FIG. 1C). In some examples, the first set of building information 132 comprises first information that is associated with (e.g., applicable to) the second building (as a whole, for example), second information that is associated with (e.g., applicable to) the first section 126 and/or third information that is associated with (e.g., applicable to) the second section 128.

In some examples, the first set of building information 132 comprises building shape information 134 indicative of a first building shape associated with the second building. In an example, the building shape information 134 comprises a building shape classification (e.g., side court, U-court, U-shape, S-court, S-shape, L-court, L-shape, multi-court, rectangle, square, oval, circle, etc.) of the first building shape and/or a representation (e.g., a graphical representation) of the first building shape. In some examples, the first building shape may be indicative of a shape and/or outline of a top of the second building, such as a shape and/or outline of the second building from an aerial perspective (e.g., a bird's-eye view and/or an overhead view). Alternatively and/or additionally, the first building shape may be indicative of a shape and/or outline of one or more other sides of the second building other than the top of the second building.

Alternatively and/or additionally, the building shape information 134 may comprise building shape classifications (e.g., L-court and/or L-shape) of building shapes of sections (e.g., the first section 126 and/or the second section 128) of the second building. Alternatively and/or additionally, the building shape information 134 may comprise representations (e.g., graphical representations) the sections of the second building.

In some examples, the first set of building information 132 comprises unit layout information 136 indicative of a unit layout associated with the second building. In an example, the unit layout information 136 comprises a unit layout classification (e.g., linear, zig zag, cyclic, z configuration, etc.) of the unit layout and/or a representation (e.g., a graphical representation) of the unit layout. In some examples, the unit layout may be indicative of an arrangement of units and/or unit numbers in the second building. Alternatively and/or additionally, the unit layout may be indicative of locations, placements, sizes and/or positions of the units in the second building. Alternatively and/or additionally, the unit layout may be indicative of a numbering sequence of the units in the second building (e.g., an ordering with which the units in the second building are numbered with unit numbers). Alternatively and/or additionally, in an example in which the second building has multiple floors, the unit layout information 136 may be indicative of multiple unit layouts associated with multiple floors of the second building. For example, the unit layout information 136 may be indicative of a unit layout (e.g., a unit layout classification and/or a representation of the unit layout) of each floor of the multiple floors.

Alternatively and/or additionally, the unit layout information 136 may comprise sets of unit layout information associated with sections (e.g., the first section 126 and/or the second section 128) of the second building. For example, a set of unit layout information associated with the first section 126 of the second building may comprise a unit layout classification of a unit layout of the first section 126 and/or a representation (e.g., a graphical representation) of the unit layout of the first section 126. Alternatively and/or additionally, the set of unit layout information may be indicative of multiple unit layouts (e.g., unit layout classifications and/or representations of unit layouts) associated with multiple floors of the first section 126.

FIG. 1E illustrates exemplary unit layouts associated with unit layout classifications. For example, a zig-zag unit layout classification may correspond to an exemplary unit numbering sequence shown in unit layout representation 149. Alternatively and/or additionally, a linear unit layout classification may correspond to an exemplary unit numbering sequence shown in unit layout representation 151. Alternatively and/or additionally, a cyclic unit layout classification may correspond to an exemplary unit numbering sequence shown in unit layout representation 153.

In some examples, such as shown in FIG. 1C, the first set of building information 132 comprises unit quantity information 138. For example, the unit quantity information 138 may comprise a number of units in the second building (e.g., the number of units may correspond to a number of units in the second building), one or more numbers of units in one or more floors of the second building (e.g., a number of units of the one or more numbers of units may correspond to a number of units in a floor of the second building), one or more numbers of units in one or more sections of the second building (e.g., a number of units of the one or more numbers of units may correspond to a number of units in a section of the second building, such as the first section 126 or the second section 128), one or more numbers of units in one or more floors of the first section 126 of the second building (e.g., a number of units of the one or more numbers of units may correspond to a number of units in a floor of the first section 126) and/or one or more numbers of units in one or more floors of the second section 128 of the second building (e.g., a number of units of the one or more numbers of units may correspond to a number of units in a floor of the second section 128).

In some examples, the first set of building information 132 comprises area information 140. For example, the area information 140 may comprise one or more measures of area (e.g., at least one of interior area, total interior area, interior livable area, total interior livable area, structure area, etc.) of the second building, one or more measures of area of one or more floors of the second building, one or more measures of area of one or more sections (e.g., the first section 126 and/or the second section 128) of the second building, one or more measures of area of one or more floors of the first section 126 and/or one or more measures of area of one or more floors of the second section 128.

In some examples, the first set of building information 132 comprises unit size information 142. For example, the unit size information 142 may comprise a range (e.g., 800 square feet to 1,200 square feet) of sizes (e.g., areas) of units in the second building, a range of sizes of units in a floor of the second building, a range of sizes of units in a section of the second building and/or a range of sizes of units in a floor of a section of the second building. Alternatively and/or additionally, the unit size information 142 may comprise unit sizes of units in the second building. Alternatively and/or additionally, the unit size information 142 may comprise an average unit size of units in the second building, an average unit size of units in a floor of the second building, an average unit size of units in a section of the second building and/or an average unit size of units in a floor of a section of the second building.

In some examples, the first set of building information 132 comprises common area information associated with one or more common areas in the second building. In some examples, a common area may correspond to an area that is not part of and/or does not belong to an individual unit of the second building. For example, a common area may be shared and/or used by visitors, residents and/or occupants of multiple units of the second building. For example, a common area may comprise at least one of a stairwell, an elevator, a public restroom, etc. In some examples, the common area information may be indicative of locations of one or more common areas in the second building, sizes of one or more common areas in the second building, dimensions of sides of one or more common areas in the second building, etc.

In some examples, the first set of building information 132 comprises at least one of one or more dimensions of the second building (e.g., the one or more dimensions may comprise at least one of one or more lengths of one or more sides of the second building, a height of the second building, etc.), one or more dimensions of a floor of the second building (e.g., the one or more dimensions may comprise at least one of one or more lengths of one or more sides of the floor, a height of the floor, etc.), one or more dimensions of a section of the second building (e.g., the one or more dimensions may comprise at least one of one or more lengths of one or more sides of the section, a height of the section, etc.), etc.

In some examples, the plurality of sets of building information 130 are identified from among a second plurality of sets of building information associated with a second plurality of buildings. In some examples, the second plurality of sets of building information is received from a floor layout provider system (e.g., a system of a floor layout provider, where the floor layout provider may receive compensation for providing the second plurality of sets of building information). Alternatively and/or additionally, the second plurality of sets of building information may be determined by physically surveying buildings of the second plurality of buildings. The first machine learning model 148 may be used to generate floor layouts of buildings, such as buildings for which floor layouts are not available in the second plurality of sets of building information. For example, by using the first machine learning model 148 to determine floor layouts associated with buildings, the floor layouts may be determined with less cost, such as a result of determining the first machine learning model 148 without paying compensation to a floor layout provider and/or without physically surveying the buildings.

In some examples, information of the second plurality of sets of building information may be used for testing, validating and/or optimizing the first machine learning model 148. For example, the second plurality of sets of building information may comprise a third plurality of sets of building information associated with a third plurality of buildings (of the second plurality of buildings), wherein the third plurality of sets of building information is used for testing, validating and/or optimizing the first machine learning model 148. The third plurality of sets of building information may be different than the plurality of sets of building information 130. Alternatively and/or additionally, the third plurality of sets of building information may be not comprise any of the plurality of sets of building information 130. In some examples, the plurality of sets of building information 130 (used for training the first machine learning model 148, for example) comprises a larger proportion of the second plurality of sets of building information than the third plurality of sets of building information (used for testing, validating and/or optimizing the first machine learning model 148, for example). In an example, the plurality of sets of building information 130 may comprise between about 60% to about 90% (e.g., about 75%) of the second plurality of sets of building information and/or the third plurality of sets of building information may comprise about 10% to about 40% (e.g., about 25%) of the second plurality of sets of building information.

In some examples, the first machine learning model 148 may be trained and/or configured to determine one or more characteristics (e.g., floor layout information) associated with a building based upon a building profile. In some examples, the first machine learning model 148 may be retrained, such as using one or more sets of building information received from a floor layout provider system, wherein the one or more sets of building information may be associated with new buildings and/or may be indicative of at least one of new building shapes, new unit layout information, etc. In an example, the first machine learning model 148 may be retrained incrementally.

Alternatively and/or additionally, the first machine learning model 148 may be retrained periodically.

At 206, a first building profile associated with the first building 158 may be generated. In some examples, the first building profile may be indicative of first geographical boundaries associated with the first building 158 and/or one or more first unit locations associated with one or more first units of the first building 158. In an example, the first geographical boundaries may correspond to geographical boundaries of the first building 158. Alternatively and/or additionally, the one or more first units associated with the one or more first unit locations may correspond to one or more units in the first building 158.

Alternatively and/or additionally, the first building profile may be associated with a section 120 of the first building 158 (shown in FIG. 1B). In an example, the first building 158 may comprise multiple structures (that are separate from each other or connected to each other) and/or the section 120 may correspond to a structure of the multiple structures (e.g., the first building 158 may comprise a multi-structure complex). For example, the first building 158 may be divided and/or split into multiple sections comprising the section 120 based upon the multiple structures, and/or the first building profile may be generated based upon the section 120. Alternatively and/or additionally, the multiple sections may correspond to multiple sections of a single structure of the first building 158. Alternatively and/or additionally, the section 120 may comprise a portion of a single structure of the first building 158. In some examples, the first geographical boundaries associated with the first building 158 may correspond to geographical boundaries of the section 120 of the first building 158. Alternatively and/or additionally, the one or more first units associated with the one or more first unit locations may correspond to one or more units in the section 120 of the first building 158.

In some examples, the first building profile may comprise a first polygon indicative of the first geographical boundaries. The first polygon may comprise a representation (e.g., a geometrical representation) of geographical boundaries of the first building 158 and/or the section 120 of the first building 158. In an example, the first polygon and/or the first geographical boundaries may be indicative of at least one of one or more locations, one or more dimensions, etc. of one or more side-edges of the first building 158 and/or the section 120 of the first building 158.

FIG. 1F illustrates an example of the first polygon (shown with reference number 156) and/or the one or more first unit locations. In some examples, the one or more first unit locations and/or one or more first unit numbers associated with the one or more first unit locations may be determined based upon unit location information. The unit location information may comprise the plurality of locations (associated with the plurality of units), a plurality of addresses associated with the plurality of locations (such as the address 124 associated with the first unit location 122) and/or a plurality of unit numbers associated with the plurality of locations (such as the unit number “110” associated with the first unit location 122). For example, the one or more first unit locations associated with the first building 150 may be identified from among the plurality of locations based upon a determination that the one or more first unit locations are within the first polygon 156 (and/or within the first geographical boundaries of the first building 158 and/or the section 120). Alternatively and/or additionally, the one or more first unit locations may be identified from among the plurality of locations based upon a determination that the one or more first unit locations are associated with one or more addresses corresponding to the first building 158 and/or the section 120 of the first building 158. In some examples, each unit number of the one or more first unit numbers may be associated with a unit location of the one or more first unit locations. For example, a unit number of the one or more first unit numbers may be determined to be associated with a unit location of the one or more first unit locations based upon an address, associated with the unit location, comprising an indication of the unit number.

In an example shown in FIG. 1F, the first polygon 156 comprises a representation of geographical boundaries of the section 120 of the first building 158 and/or the one or more first units associated with the one or more first unit locations are in the section 120 of the first building 158. The one or more first unit locations may comprise the first unit location 122 associated with the unit number “110” of the section 120 of the first building 158, a second unit location 162 associated with unit number “102” of the section 120 of the first building 158, a third unit location 164 associated with unit number “103” of the section 120 of the first building 158 and/or a fourth unit location 166 associated with unit number “105” of the section 120 of the building 158. The one or more first unit numbers may comprise the unit number “110”, the unit number “102”, the unit number “103” and/or the unit number “105”. In the example shown in FIG. 1F, the one or more first units associated with the one or more first unit locations do not comprise a unit outside the section 120 of the first building 158. It may be appreciated that in some embodiments, such as when the first building profile is associated with the first building 158 (as a whole, for example), the one or more first units associated with the one or more first unit locations comprise one or more units that are outside the section 120 and within the first building 158 and/or the polygon 156 comprises a representation of geographical boundaries of the first building 158 (rather than comprising a representation of geographical boundaries of merely the section 120 of the first building 158, for example).

In some examples, the one or more first unit locations and/or the one or more first unit numbers associated with the one or more first unit locations may be associated with a first floor (e.g., floor 1, floor 2, floor 3, etc.) of the first building 158 and/or the section 120 of the first building 158. For example, the one or more first units, associated with the one or more first unit locations and/or the one or more first unit numbers, may be in the first floor of the first building 158 and/or the section 120.

In some examples, the first building profile comprises the first polygon 156, the one or more first unit locations, the one or more first unit numbers associated with the one or more first unit locations, a number of floors of the first building 158 (and/or a number of floors of the section 120) and/or an indication that the one or more first units (associated with the one or more first unit locations and/or the one or more first unit numbers) are in the first floor. In some examples, such as where the first building 158 and/or the section 120 have multiple floors, the first building profile may comprise one or more other unit locations and/or one or more other unit numbers associated with one or more other units in one or more other floors (e.g., one or more floors other than the first floor). For example, the first building profile may be indicative of a floor associated with a unit of the one or more other units (e.g., for each unit location of the one or more other unit locations and/or for each unit number of the one or more other unit numbers, the first building profile may be indicative of a floor associated with the unit location and/or the unit number).

At 208, a first unit number configuration and/or second building shape information associated with the first building 158 may be determined using the first machine learning model 148. In some examples, the first unit number configuration may be indicative of a second unit layout classification (e.g., linear, zig zag, cyclic, z configuration, etc.) of the first building 158 and/or of the section 120 of the first building 158. In some examples, the first unit number configuration may be indicative of an arrangement of units and/or unit numbers in the first building 158 and/or in the section 120 of the first building 158. Alternatively and/or additionally, the first unit number configuration may be indicative of a numbering sequence of the units in the first building 158 and/or in the section 120 of the first building 158 (e.g., an ordering with which the units in the first building 158 and/or the section 120 are numbered with unit numbers). Alternatively and/or additionally, the first unit number configuration may comprise a representation (e.g., a graphical representation) of a second unit layout of the first building 158 and/or of the section 120 of the first building 158.

In some examples, the second building shape information associated with the first building 158 may be indicative of a second building shape of the first building 158 and/or of the section 120 of the first building 158. In an example, the second building shape information comprises a second building shape classification (e.g., side court, U-court, U-shape, S-court, S-shape, L-court, L-shape, multi-court, rectangle, square, oval, circle, etc.) of the second building shape and/or a representation (e.g., a graphical representation) of the second building shape.

FIG. 1G illustrates floor layout information 174, comprising the first unit number configuration and/or the second building shape information, being determined using the first machine learning model 148. In an example, the first machine learning model 148 may be loaded into a layout prediction module 172. In some examples, the first machine learning model 148 may comprise a deep learning model, such as a convolutional neural network model. Alternatively and/or additionally, the first machine learning model 148 may comprise at least one of a neural network, a tree-based model, a machine learning model used to perform linear regression, a machine learning model used to perform logistic regression, a decision tree model, a support vector machine (SVM), a Bayesian network model, a k-Nearest Neighbors (kNN) model, a K-Means model, a random forest model, a machine learning model used to perform dimensional reduction, a machine learning model used to perform gradient boosting, etc. Alternatively and/or additionally, the layout prediction module 172 may comprise a deep learning machine learning algorithm, such as a convolutional neural network deep learning machine learning algorithm (and/or the layout prediction module 172 may use the deep learning machine learning algorithm to determine the floor layout information 174). For example, the first building profile (shown with reference number 170 in FIG. 1G) may be input to the layout prediction module 172. The layout prediction module 172 may use the deep learning machine learning algorithm and/or the first machine learning model 148 to determine the floor layout information 174 based upon the first building profile 170. For example, the floor layout information 174 may be output by the layout prediction module 172.

In an example, such as shown in FIG. 1G, the first unit number configuration may be indicative of the second unit layout classification corresponding to a zig-zag unit layout. Alternatively and/or additionally, the floor layout information 174 may comprise a first confidence score (e.g., 0.81) of the first unit number configuration. In some examples, the first confidence score may be compared with a first threshold confidence score (e.g., 0.7). In some examples, based upon a determination that the first confidence score does not meet the first threshold confidence score, the first unit number configuration may not be used for generating a floor layout associated with the first building 158 and/or the section 120 of the first building 158. In some examples, based upon a determination that the first confidence score does not meet the first threshold confidence score, the first unit number configuration (and/or the floor layout information 174) may be determined to be an unreliable source of data for use in generating a floor layout and/or determining locations of units in the first building 158 and/or the section 120.

In an example, such as shown in FIG. 1G, the second building shape information may be indicative of the second building shape classification corresponding to a rectangle building shape. Alternatively and/or additionally, the floor layout information 174 may comprise a second confidence score (e.g., 0.93) of the second building shape information. In some examples, the second confidence score may be compared with a second threshold confidence score (e.g., 0.7). In some examples, based upon a determination that the second confidence score does not meet the second threshold confidence score, the second building shape information may not be used for generating a floor layout associated with the first building 158 and/or the section 120 of the first building 158. In some examples, based upon a determination that the second confidence score does not meet the second threshold confidence score, the second building shape information (and/or the floor layout information 174) may be determined to be an unreliable source of data for use in generating a floor layout and/or determining locations of units in the first building 158 and/or the section 120.

In some examples, such as shown in FIG. 1G, the floor layout information 174 comprises a unit spacing parameter (e.g., 30 feet), such as unit distance and/or unit spread, associated with the first building 158 and/or associated with the section 120 of the first building 158. In some examples, the unit spacing parameter may correspond to a distance between locations of adjacent units in the first building 158 and/or in the section 120 of the first building 158. In an example, the unit spacing parameter may correspond to a distance between centers of adjacent units in the first building 158 and/or in the section 120 of the first building 158. In an example shown in FIG. 1H, a distance 184 between two adjacent unit locations (associated with unit numbers “104” and “106”, for example) may be determined based upon the unit spacing parameter (e.g., the distance 184 may be equal to the unit spacing parameter and/or one or more mathematical operations may be performed using the unit spacing parameter to determine the distance 184). Alternatively and/or additionally, the floor layout information 174 may comprise a third confidence score (e.g., 0.83) of the unit spacing parameter. In some examples, the third confidence score may be compared with a third threshold confidence score (e.g., 0.7). In some examples, based upon a determination that the third confidence score does not meet the third threshold confidence score, the unit spacing parameter may not be used for generating a floor layout associated with the first building 158 and/or the section 120 of the first building 158. In some examples, based upon a determination that the third confidence score does not meet the third threshold confidence score, the unit spacing parameter (and/or the floor layout information 174) may be determined to be an unreliable source of data for use in generating a floor layout and/or determining locations of units in the first building 158 and/or the section 120.

In some examples, the floor layout information 174 may comprise a set of unit locations of units in the first building 148 and/or in the section 120 of the first building 158 and/or a set of unit numbers associated with the set of unit locations. A unit location of the set of unit locations may be associated with a unit number of the set of unit numbers (e.g., each unit location of the set of unit locations may be associated with a unit number of the set of unit numbers). For example, a unit location of the set of unit locations may correspond to a location of a unit having a unit number of the set of unit numbers. Alternatively and/or additionally, the floor layout information 174 may comprise a fourth confidence score of the set of unit locations. In some examples, the fourth confidence score may be compared with a fourth threshold confidence score (e.g., 0.7). In some examples, based upon a determination that the fourth confidence score does not meet the fourth threshold confidence score, the set of unit locations may not be used for generating a floor layout associated with the first building 158 and/or the section 120 of the first building 158. In some examples, based upon a determination that the fourth confidence score does not meet the fourth threshold confidence score, the set of unit locations (and/or the floor layout information 174) may be determined to be an unreliable source of data for use in generating a floor layout and/or determining locations of units in the first building 158 and/or the section 120.

In some examples, the floor layout information 174 may comprise a set of common area locations of one or more common areas in the first building 148 and/or in the section 120 of the first building 158. Alternatively and/or additionally, the floor layout information 174 may comprise a fifth confidence score of the set of common area locations. In some examples, the fifth confidence score may be compared with a fifth threshold confidence score (e.g., 0.7). In some examples, based upon a determination that the fifth confidence score does not meet the fifth threshold confidence score, the set of common area locations may not be used for generating a floor layout associated with the first building 158 and/or the section 120 of the first building 158. In some examples, based upon a determination that the fifth confidence score does not meet the fifth threshold confidence score, the set of common area locations (and/or the floor layout information 174) may be determined to be an unreliable source of data for use in generating a floor layout and/or determining locations of units in the first building 158 and/or the section 120.

The floor layout information 174 may be associated with (and/or applicable to) the first floor. In an example in which the first building 158 and/or the section 120 have the multiple floors, a plurality of sets of floor layout information 178 may be determined (using the first machine learning model 148 and/or the layout prediction module 172). For example, a set of floor layout information of the plurality of sets of floor layout information 178 may be associated with (and/or applicable to) a floor of the multiple floors. For example, a first set of floor layout information may comprise the floor layout information 174 associated with (and/or applicable to) the first floor, a second set of floor layout information may comprise second floor layout information associated with (and/or applicable to) a second floor of the multiple floors, etc.

In some examples, the floor layout information 174 associated with the first floor may be determined (using the first machine learning model 148 and/or the layout prediction module 172) based upon the one or more first unit locations and/or the one or more first unit numbers associated with the one or more first units in the first floor. In some examples, the set of unit locations of the floor layout information 174 may comprise locations of second units in the first floor and/or the set of unit numbers may comprise unit numbers of the second units, wherein the second units may comprise one or more third units for which the first building profile 170 does not indicate a unit location and/or a unit number (and/or for which a unit location and/or a unit number are not indicated by the plurality of locations 112). In some examples, one or more unit locations and/or one or more unit numbers of at least some of the one or more third units (for which the first building profile 170 does not indicate a unit location and/or a unit number, for example) may be extrapolated (e.g., linearly extrapolated) from the one or more first unit locations and/or the one or more first unit numbers associated with the one or more first units in the first floor (using the first machine learning model 148 and/or the layout prediction module 172, for example).

Alternatively and/or additionally, in an example in which the first building 158 and/or the section 120 have the multiple floors, the floor layout information 174 associated with the first floor may be determined (using the first machine learning model 148 and/or the layout prediction module 172) based upon the one or more other unit locations and/or the one or more other unit numbers associated with the one or more other units in the one or more other floors (other than the first floor) of the multiple floors. In some examples, one or more unit locations and/or one or more unit numbers of at least some of the one or more third units (for which the first building profile 170 does not indicate a unit location and/or a unit number, for example) may be extrapolated (e.g., vertically extrapolated) from the one or more other unit locations and/or the one or more other unit numbers associated with the one or more other units in the one or more other floors (using the first machine learning model 148 and/or the layout prediction module 172, for example). In an example in which the one or more other unit locations comprise a unit location, on floor 3, corresponding to unit number “301”, at least one of a unit location corresponding to unit number “101” (on floor 1, for example), a unit location corresponding to unit number “201” (on floor 2, for example), a unit location corresponding to unit number “401” (on floor 4, for example), etc., may be vertically extrapolated from the unit location corresponding to unit number “301”. For example, a horizontal position of at least one of the unit location corresponding to unit number “101”, the unit location corresponding to unit number “201”, the unit location corresponding to unit number “401”, etc. may be determined based upon the unit location corresponding to unit number “301”.

At 210, a first floor layout associated with the first building 158 may be generated based upon the floor layout information 174. For example, the first floor layout may be generated based upon at least one of the first unit number configuration, the second building shape information, the unit spacing parameter, the set of unit locations of units in the first building 148 and/or in the section 120 of the first building 158, the set of common area locations of one or more common areas in the first building 148 and/or in the section 120 of the first building 158, etc.

Alternatively and/or additionally, in an example in which the first building 158 and/or the section 120 have the multiple floors, a plurality of floor layouts, comprising the first floor layout, may be generated based upon the plurality of sets of floor layout information 178 associated with the multiple floors. For example, a floor layout, of the plurality of floor layouts, corresponding to a floor of the multiple floors, may be generated based upon a set of floor layout information, of the plurality of sets of floor layout information 178, associated with (and/or applicable to) the floor.

In some examples, the first floor layout associated with the first building 158 may be generated in response to determining that the first confidence score of the first unit number configuration exceeds the first threshold confidence score, the second confidence score of the second building shape information exceeds the second threshold confidence score, the third confidence score of the unit spacing parameter exceeds the third threshold confidence score, the fourth confidence score of the set of unit locations exceeds the fourth threshold confidence score and/or the fifth confidence score of the set of common area locations exceeds the fifth threshold confidence score.

FIG. 1H illustrates the first floor layout (shown with reference number 182 in FIG. 1H) being determined based upon the floor layout information 174. Alternatively and/or additionally, in an example in which the first building 158 and/or the section 120 have the multiple floors, the plurality of floor layouts (shown with reference number 180) may be determined based upon the plurality of sets of floor layout information 178.

In some examples, the first floor layout 182 may be indicative of an arrangement of units in the first building 158 and/or the section 120, and/or indicative of unit numbers associated with the units. For example, the first floor layout 182 may be indicative of an arrangement of the second units in the first floor. In an example in which the first building profile 170, the first polygon 156 and/or the floor layout information 174 correspond to the section 120 of the first building 158, the second units may comprise units in the first floor that are within the section 120 of the first building 158 (and/or may not comprise units that are not in the within the section 120). Alternatively and/or additionally, in an example in which the first building profile 170, the first polygon 156 and/or the floor layout information 174 correspond to the first building 158 (as a whole, for example), the second units may comprise units in the first floor of the first building 158 that are within the section 120 of the first building 158 and outside the section 120. Alternatively and/or additionally, the first floor layout 182 may be indicative of the second unit numbers associated with the second units.

In some examples, the first floor layout 182 may be indicative of a second set of unit locations comprising locations of the second units. In an example in which the floor layout information 174 comprises the set of unit locations, the second set of unit locations may be the same as the set of unit locations. Alternatively and/or additionally, in an example in which the floor layout information 174 comprises the set of unit locations, the second set of unit locations may be different than the set of unit locations. In some examples, a location of the second set of unit locations may be indicative of a location of a point (e.g., a centroid or other point) within a unit of the second units. Alternatively and/or additionally, a location of the second set of unit locations may be indicative of one or more geographical boundaries of a unit of the second units and/or one or more locations, one or more dimensions, etc. of one or more side-edges of a unit of the second units.

Alternatively and/or additionally, the first floor layout 182 may be indicative of a second set of common area locations of one or more common areas in the first floor. In an example in which the first building profile 170, the first polygon 156 and/or the floor layout information 174 correspond to the section 120 of the first building 158, the second set of common area locations may comprise locations of one or more common areas in the first floor that are within the section 120 of the first building 158 (and/or may not comprise locations of one or more common areas that are not within the section 120). Alternatively and/or additionally, in an example in which the first building profile 170, the first polygon 156 and/or the floor layout information 174 correspond to the first building 158 (as a whole, for example), the second set of common area locations may comprise locations of one or more common areas in the first floor that are within the section 120 of the first building 158 and outside the section 120. In an example in which the floor layout information 174 comprises the set of common area locations, the second set of common area locations may be the same as the set of common area locations. Alternatively and/or additionally, in an example in which the floor layout information 174 comprises the set of common area locations, the second set of common area locations may be different than the set of common area locations. In some examples, a location of the second set of common area locations may be indicative of a location of a point (e.g., a centroid or other point) within a common area. Alternatively and/or additionally, a location of the second set of common area locations may be indicative of one or more geographical boundaries of a common area and/or one or more locations, one or more dimensions, etc. of one or more side-edges of the common area.

In some examples, the first floor layout 182 may be validated based upon one or more unit locations of the second set of unit locations (as indicated by the first floor layout 182, for example) and/or the one or more first unit locations (of the unit location information, for example). For example, a distance between a unit location of the second set of unit locations and a unit location of the one or more first unit locations may be determined, wherein the unit location of the second set of unit locations and the unit location of the one or more first unit locations are associated with the same unit number. The distance may be compared with a threshold distance to determine whether the unit location of the second set of unit locations and/or the first floor layout 182 are valid. In some examples, the unit location of the second set of unit locations may be determined to be valid based upon a determination that the distance is less than the threshold distance. Alternatively and/or additionally, the unit location of the second set of unit locations may be determined to be invalid (and/or incorrect) based upon a determination that the distance exceeds the threshold distance. In some examples, the threshold distance is based upon and/or equal to the unit spacing parameter. Alternatively and/or additionally, the threshold distance may be different than (and/or may not be based upon) the unit spacing parameter.

In an example, the second set of unit locations (as indicated by the first floor layout 182, for example) may comprise a fifth unit location 186 (shown in FIG. 1H) associated with the unit number “110”. A first distance between the first unit location 122 (shown in FIG. 1B and FIG. 1F) associated with the unit number “110” and the fifth unit location 186 associated with the unit number “110” may be determined. The first distance may be compared with the threshold distance to determine whether the fifth unit location 186 and/or the first floor layout 182 are valid. The fifth unit location 186 may be determined to be valid based upon a determination that the first distance is less than the threshold distance. The fifth unit location 186 may be determined to be invalid (and/or incorrect) based upon a determination that the first distance exceeds the threshold distance. In some examples, in response to determining that the first distance exceeds the threshold distance, the fifth unit location 186 may be modified (and/or one or more other unit locations of the second set of unit locations may be modified) such that the first distance between the fifth unit location 186 and the first unit location 122 is less than the threshold distance. In some examples, one or more other unit locations of the second set of unit locations may be validated and/or modified, such as using one or more of the techniques described herein with respect to validating and/or modifying the fifth unit location 186 based upon the distance between the fifth unit location 186 associated with the unit number “110” and the first unit location 122 associated with the unit number “110”.

In some examples, the first floor layout 182 may be transmitted to and/or stored on the floor layout system 114. Alternatively and/or additionally, in an example in which the first building 158 and/or the section 120 have the multiple floors, the plurality of floor layouts 180 may be transmitted to and/or stored on the floor layout system 114. In some examples, the floor layout system 114 may comprise an indication that the first floor layout 182 (and/or the plurality of floor layouts 180) is associated with a first address (e.g., an address comprising one or more indications of at least one of a street number, a street, a building name, a range of unit numbers of the first floor layout 182 and/or the plurality of floor layouts 180, a city, a state, a zip code, etc.) of the first building 158 and/or the section 120 of the first building 158. In an example, the first address may be determined based upon one or more addresses associated with the one or more first unit locations (such as the address 124 shown in FIG. 1B). In an example, the first address may be 20 East 15th St, Atlanta, Ga. In some examples, the floor layout system 114 may comprise and/or store unit location determination information. The unit location determination information comprises a plurality of sets of floor layouts associated with a plurality of buildings. The unit location determination information comprises a plurality of addresses associated with the plurality of sets of floor layouts. For example, a set of floor layouts (e.g., a set of one or more floor layouts) of the plurality of sets of floor layouts (and/or each set of floor layouts of the plurality of sets of floor layouts) may comprise one or more floor layouts associated with an address of the plurality of addresses and/or a building of the plurality of buildings. In an example, the plurality of addresses comprises the first address. Alternatively and/or additionally, the plurality of sets of floor layouts may comprise a first set of floor layouts associated with the first address and/or the first building 158 and/or the section 120 of the first building 158. The first set of floor layouts may comprise the first floor layout 182 (and/or the plurality of floor layouts 180).

In some examples, the first floor layout 182 (and/or the plurality of floor layouts 180) may be used to determine one or more unit locations associated with one or more unit numbers. In an example, a unit number associated with the first building 158 and/or the section 120 may be received (e.g., the unit number may be identified in an address that is received, such as by the floor layout system 114). A location of a unit associated with the unit number may be determined (by the floor layout system 114, for example) based upon the first floor layout 182 (and/or the plurality of floor layouts 180). In some examples, the location of the unit may be determined based upon the first floor layout 182 (and/or the location of the unit may be used to perform a service, such as a service discussed below) based upon a determination that the first confidence score of the first unit number configuration exceeds the first threshold confidence score, the second confidence score of the second building shape information exceeds the second threshold confidence score, the third confidence score of the unit spacing parameter exceeds the third threshold confidence score, the fourth confidence score of the set of unit locations exceeds the fourth threshold confidence score and/or the fifth confidence score of the set of common area locations exceeds the fifth threshold confidence score.

Alternatively and/or additionally, the location of the unit may not be determined based upon the first floor layout 182 based upon a determination that the first confidence score of the first unit number configuration does not meet the first threshold confidence score, the second confidence score of the second building shape information does not meet the second threshold confidence score, the third confidence score of the unit spacing parameter does not meet the third threshold confidence score, the fourth confidence score of the set of unit locations does not meet the fourth threshold confidence score and/or the fifth confidence score of the set of common area locations does not meet the fifth threshold confidence score. For example, one or more instructions may be transmitted (by the floor layout system 114, for example) to a client device associated with the unit, wherein the one or more instructions may be indicative of inputting (e.g., manually inputting) a location of the unit via an interface (e.g., a map interface for selecting and/or sharing locations) of the client device and/or transmitting the location to the floor layout system 114. Alternatively and/or additionally, the interface may be presented via the client device and/or the location of the unit may be input (e.g., manually input) via the interface. The client device may transmit the location of the unit to the floor layout system 114. In some examples, a service may be performed based upon the location of the unit (such as using one or more of the techniques discussed below). Alternatively and/or additionally, the location of the unit and/or the unit number associated with the location of the unit may be used (along with the one or more first unit locations and/or the one or more first unit numbers previously received and/or determined by the floor layout system 114, for example) to generate and/or update the building profile 170, the floor layout information 174 and/or the first floor layout 182, such as using one or more of the techniques herein. It may be appreciated that by using the location of the unit and/or the unit number to generate and/or update the building profile 170, the floor layout information 174 and/or the first floor layout 182, one or more confidence scores of the floor layout information 174 may be increased and/or an accuracy of the first floor layout 182 may be increased.

FIG. 1I illustrates a first request 190 for a first service being received by the floor layout system 114 from a first client device 100. In some examples, the first service may be associated with a first unit of a building. For example, a location of the first unit may be used (and/or required) for performing the first service. In some examples, an address 192 associated with the first unit may be determined in response to receiving the first request 190. In some examples, the address 192 may be determined based upon the first request 190. For example, the first request 190 may be indicative of the address 192. Alternatively and/or additionally, the first request 190 may be determined based upon a client identifier (e.g., the client identifier may be indicated by the first request 190 and/or received from the first client device 100). The client identifier may identify at least one of the first client device 100, a user account of the first client device 100, a cookie (e.g., a browser cookie), etc. For example, client address information comprising a plurality of addresses and/or a plurality of client identifiers may be analyzed based upon the client identifier to identify the address 192. The address 192 may be identified based upon a determination that the client address information indicates that the client identifier (indicated by the first request 190 and/or received from the first client device 100, for example) is associated with the address 192.

In some examples, in response to determining the address 192 associated with the first client device 100, the unit location determination information may be analyzed to identify a floor layout associated with the address 192. For example, the plurality of addresses of the unit location determination information may be analyzed to identify an address, in the plurality of addresses, that matches the address 192. In an example, it may be determined that an address of the plurality of addresses matches the address 192 based upon a determination that at least one of a street number of the address is the same as and/or corresponds to a street number of the address 192, a street of the address is the same as and/or corresponds to a street of the address 192, a building name of the address is the same as and/or corresponds to a building name of the address 192, a range of unit numbers of the address comprises a unit number of the address 192, a city of the address is the same as and/or corresponds to a city of the address 192, a state of the address is the same as and/or corresponds to a state of the address 192, a zip code of the address is the same as and/or corresponds to a zip code of the address 192, etc. In an example, it may be determined that the address 192 matches the first address associated with the first set of floor layouts (comprising the first floor layout 182 and/or the plurality of floor layouts 180, for example).

FIG. 1J illustrates a sixth unit location 188 (also shown in FIG. 1H within the first floor layout 182) of the first unit associated with the first service being determined. In some examples, the first set of floor layouts (e.g., the first floor layout 182 and/or the plurality of floor layouts 180) may be analyzed based upon a first unit number (e.g., unit number “106”) indicated by the address 192 to identify the sixth unit location 188 associated with the first unit number. In some examples, the first unit number may be determined by analyzing the address 192. In an example, the first unit number may be identified based upon a determination that the first unit number is preceded by a set of one or more unit number designation characters, such as at least one of “Unit”, “Unit number”, “Unit #”, “Apartment”, “Apartment number”, “APT”, “APT #”, “Suite”, “Suite number”, “STE”, “STE #”, “#”, “Number”, etc. The first unit number may comprise one or more characters (e.g., “106”), such as at least one of one or more numbers, one or more letters, one or more symbols, etc. that identify the first unit.

Accordingly, it may be determined that the first unit associated with the first unit number has the sixth unit location 188 (shown in FIG. 1H) based upon a determination that the first floor layout 182 (and/or the second set of unit locations) comprises the sixth unit location 188 associated with the first unit number (e.g., “106”). For example, it may be determined that the first unit associated with the first unit number has the sixth unit location 188 based upon a determination that the first floor layout 182 is indicative of the sixth unit location 188 being associated with the first unit number (e.g., “106”). Alternatively and/or additionally, it may be determined that the first unit is on the first floor of the first building 158 and/or of the section 120 of the first building based upon the first floor layout 182 being indicative of the first unit associated with the first unit number being on the first floor. In some examples, an altitude of the first unit may be determined based upon the first floor and/or one or more heights of one or more floors of the first building 158 and/or of the section 120 of the first building 158. For example, the one or more heights of the one or more floors may be determined based upon the first set of floor layouts (e.g., the first floor layout 182 and/or the plurality of floor layouts 180). For example, the first set of floor layouts may be indicative of the one or more heights of the one or more floors.

In some examples, the first service may be performed (by the floor layout system 114, for example) based upon the sixth unit location 188. In an example, the first service may comprise determining whether the first unit is within coverage of a second service, such as at least one of a cellular service (e.g., 5G service, 4G service and/or other type of cellular service), an internet service (e.g., cellular internet service, cable internet, digital subscriber line (DSL) internet service, satellite internet service, 5G internet service, and/or other type of internet service), a television service (e.g., wireless television service, cable TV service, and/or other television service), etc. The sixth unit location 188 may be compared with one or more regions that are associated with coverage of the second service. It may be determined that the first unit is within coverage of the second service based upon a determination that the sixth unit location 188 is within a region associated with coverage of the second service. Alternatively and/or additionally, it may be determined that the first unit is not within coverage of the second service based upon a determination that the sixth unit location 188 is not within a region associated with coverage of the second service.

In some examples, the sixth unit location 188 of the first unit within the first building 158 may impact whether the first unit is within coverage of the second service. For example, one or more first portions of the first building 158 may be within coverage of the second service, and one or more second portions of the first building 158 may not be within coverage of the second service. In an example, a first side (e.g., a north side) of the first building 158 may be within coverage of the second service and a second side (e.g., a south side) of the first building 158 may not be within coverage of the second service. In some examples, the one or more first portions and/or the first side of the first building 158 may be within coverage of the second service and/or the one or more second portions and/or the second side of the first building 158 may not be within coverage of the second service due to one or more positions of one or more stations (e.g., at least one of one or more networks, one or more base stations, one or more cell towers, etc.) associated with the second service. In an example, the second service may comprise a wireless service (e.g., 5G service or other wireless service), wherein signals transmitted wirelessly are impacted by obstructions such as at least one of walls, buildings, windows, etc. Thus, using the sixth unit location 188 of the first unit within the first building 158 to determine whether the first unit is within coverage of the second service may provide for a more accurate determination of whether the first unit is within coverage of the second service (as compared to using a building location of the building 158 and/or a section location of the section 120 to determine whether the first unit is within coverage of the second service).

In some examples, in response to determining whether the first unit is within coverage of the second service, an indication of whether the first unit is within coverage of the second service may be transmitted (by the floor layout system 114, for example) to the first client device 100 and/or to one or more devices associated with installing one or more components associated with the second service and/or activating the second service. In some examples, in response to determining that the first unit is within coverage of the second service, at least one of a receiver, a router, a modem, a client device, etc. associated with the second service may be installed at the first unit and/or activated for use at the first unit. Alternatively and/or additionally, in response to determining that the first unit is within coverage of the second service, the floor layout system 114 may provide service information via an interface, such as an API and/or a GUI to allow for information display. In some examples, the service information may be indicative of at least one of the address 192, the second service (and/or a service plan of the second service), the sixth unit location 188 of the first unit, the first floor of the first unit, etc. In some examples, the service information may be used by one or more entities, such as at least one of an engagement manager, a technician, etc. to provide the second service to one or more users in the first unit. For example, based upon the service information, at least one of a receiver, a router, a modem, a client device, etc. associated with the second service may be installed at the first unit and/or activated for use at the first unit.

In an example, the first service may comprise a delivery service. For example, in response to determining the sixth unit location 188 of the first unit, the floor layout system 114 may provide delivery information via an interface, such as an API and/or a GUI to allow for information display. For example, the delivery information may be indicative of at least one of the address 192, the sixth unit location 188 of the first unit, one or more items (e.g., at least one of a food order, a package, one or more products, one or more goods, one or more services, etc.) to be delivered to the first unit, the first floor of the first unit, etc. In some examples, the delivery information may be used by one or more entities, such as at least one of a delivery person, a business, etc., to deliver the one or more items to the first unit.

According to some embodiments, a method is provided. The method includes identifying a plurality of sets of building information associated with a plurality of buildings, wherein a first set of building information of the plurality of sets of building information is indicative of unit layout information associated with a first building of the plurality of buildings; training a machine learning model using the plurality of sets of building information to generate a trained machine learning model; generating a building profile associated with a second building, wherein the building profile is indicative of geographical boundaries associated with the second building and one or more locations associated with one or more units in the second building; determining, using the trained machine learning model, a unit number configuration associated with the second building based upon the building profile; and generating, based upon the unit number configuration, a first floor layout associated with the second building, wherein the first floor layout is indicative of a first arrangement of first units in the second building and first unit numbers associated with the first units.

According to some embodiments, the method includes receiving a unit number of a unit in the second building; and determining, based upon the first floor layout, a location of the unit.

According to some embodiments, the method includes determining, based upon the location of the unit, whether the unit is within coverage of a service.

According to some embodiments, the method includes receiving the one or more locations from one or more client devices.

According to some embodiments, the first set of building information of the plurality of sets of building information is indicative of a building shape associated with the first building.

According to some embodiments, the method includes determining, using the trained machine learning model, building shape information associated with the second building based upon the building profile, wherein the generating the first floor layout is performed based upon the building shape information.

According to some embodiments, the method includes determining, using the trained machine learning model, a confidence score of the building shape information, wherein the generating the first floor layout based upon the building shape information is performed based upon a determination that the confidence score exceeds a threshold confidence score.

According to some embodiments, the method includes determining, using the trained machine learning model, a unit spacing parameter associated with the second building based upon the building profile, wherein the generating the first floor layout is performed based upon the unit spacing parameter.

According to some embodiments, the method includes determining, using the trained machine learning model, a confidence score of the unit spacing parameter, wherein the generating the first floor layout based upon the unit spacing parameter is performed based upon a determination that the confidence score exceeds a threshold confidence score.

According to some embodiments, the method includes determining, using the trained machine learning model, a confidence score of the unit number configuration, wherein the generating the first floor layout based upon the unit number configuration is performed based upon a determination that the confidence score exceeds a threshold confidence score.

According to some embodiments, the first arrangement of the first units is indicative of first locations of the first units.

According to some embodiments, the geographical boundaries of the building profile include geographical boundaries of a section of the second building; and the first units are in the section of the second building.

According to some embodiments, a non-transitory computer-readable medium, storing instructions that when executed perform operations, is provided. The operations include identifying a plurality of sets of building information associated with a plurality of buildings, wherein a first set of building information of the plurality of sets of building information is indicative of unit layout information associated with a first building of the plurality of buildings; training a machine learning model using the plurality of sets of building information to generate a trained machine learning model; generating a building profile associated with a section of a second building, wherein the building profile is indicative of geographical boundaries of the section of the second building and one or more locations associated with one or more units in the section of the second building; determining, using the trained machine learning model, a unit number configuration associated with the section of the second building based upon the building profile; and generating, based upon the unit number configuration, a first floor layout associated with the section of the second building, wherein the first floor layout is indicative of a first arrangement of first units in the section of the second building and first unit numbers associated with the first units.

According to some embodiments, the operations include receiving a unit number of a unit in the section of the second building; and determining, based upon the first floor layout, a location of the unit.

According to some embodiments, the operations include determining, based upon the location of the unit, whether the unit is within coverage of a service.

According to some embodiments, the first set of building information of the plurality of sets of building information is indicative of a building shape associated with the first building.

According to some embodiments, the operations include determining, using the trained machine learning model, building shape information associated with the section of the second building based upon the building profile, wherein the generating the first floor layout is performed based upon the building shape information.

According to some embodiments, the operations include determining, using the trained machine learning model, a confidence score of the building shape information, wherein the generating the first floor layout based upon the building shape information is performed based upon a determination that the confidence score exceeds a threshold confidence score.

According to some embodiments, a device is provided. The device includes a processor coupled to memory, the processor configured to execute instructions to perform operations. The operations include identifying a plurality of sets of building information associated with a plurality of buildings, wherein a first set of building information of the plurality of sets of building information is indicative of unit layout information associated with a first building of the plurality of buildings; training a machine learning model using the plurality of sets of building information to generate a trained machine learning model; generating a building profile associated with a second building, wherein the building profile is indicative of geographical boundaries associated with the second building and one or more locations associated with one or more units in the second building; determining, using the trained machine learning model, a unit number configuration associated with the second building based upon the building profile; and generating, based upon the unit number configuration, a first floor layout associated with the second building, wherein the first floor layout is indicative of a first arrangement of first units in the second building and first unit numbers associated with the first units.

According to some embodiments, the operations include determining, based upon the first floor layout, a location of a unit in the second building; and determining, based upon the location of the unit, whether the unit is within coverage of a service.

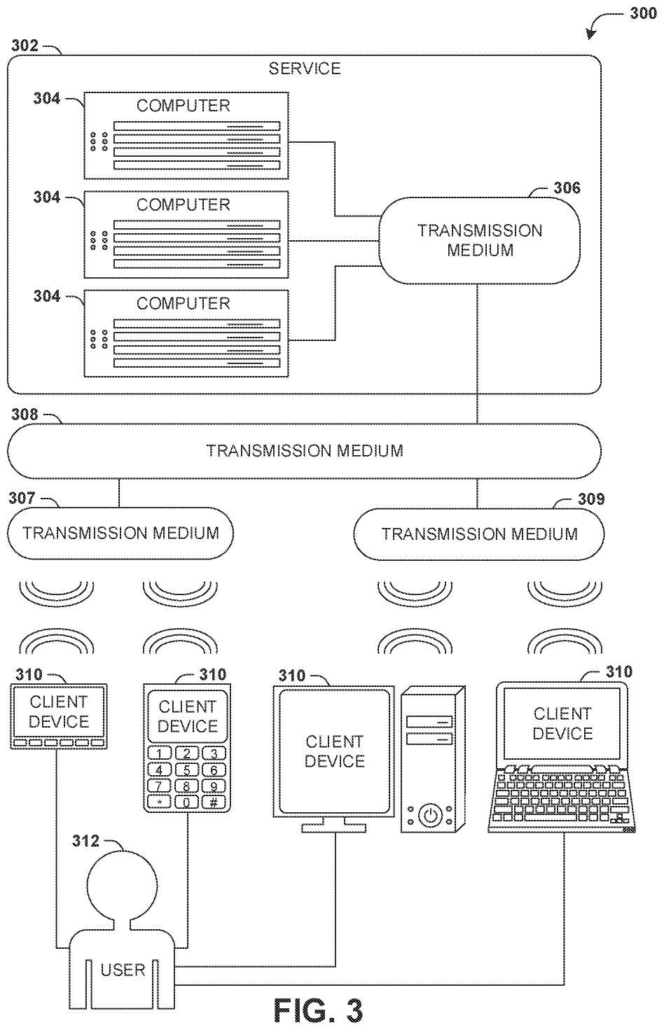

FIG. 3 is an interaction diagram of a scenario 300 illustrating a service 302 provided by a set of computers 304 to a set of client devices 310 via various types of transmission mediums. The computers 304 and/or client devices 310 may be capable of transmitting, receiving, processing, and/or storing many types of signals, such as in memory as physical memory states.

The computers 304 of the service 302 may be communicatively coupled together, such as for exchange of communications using a transmission medium 306. The transmission medium 306 may be organized according to one or more network architectures, such as computer/client, peer-to-peer, and/or mesh architectures, and/or a variety of roles, such as administrative computers, authentication computers, security monitor computers, data stores for objects such as files and databases, business logic computers, time synchronization computers, and/or front-end computers providing a user-facing interface for the service 302.

Likewise, the transmission medium 306 may comprise one or more sub-networks, such as may employ different architectures, may be compliant or compatible with differing protocols and/or may interoperate within the transmission medium 306. Additionally, various types of transmission medium 306 may be interconnected (e.g., a router may provide a link between otherwise separate and independent transmission medium 306).

In scenario 300 of FIG. 3, the transmission medium 306 of the service 302 is connected to a transmission medium 308 that allows the service 302 to exchange data with other services 302 and/or client devices 310. The transmission medium 308 may encompass various combinations of devices with varying levels of distribution and exposure, such as a public wide-area network and/or a private network (e.g., a virtual private network (VPN) of a distributed enterprise).

In the scenario 300 of FIG. 3, the service 302 may be accessed via the transmission medium 308 by a user 312 of one or more client devices 310, such as a portable media player (e.g., an electronic text reader, an audio device, or a portable gaming, exercise, or navigation device); a portable communication device (e.g., a camera, a phone, a wearable or a text chatting device); a workstation; and/or a laptop form factor computer. The respective client devices 310 may communicate with the service 302 via various communicative couplings to the transmission medium 308. As a first such example, one or more client devices 310 may comprise a cellular communicator and may communicate with the service 302 by connecting to the transmission medium 308 via a transmission medium 307 provided by a cellular provider. As a second such example, one or more client devices 310 may communicate with the service 302 by connecting to the transmission medium 308 via a transmission medium 309 provided by a location such as the user's home or workplace (e.g., a WiFi (Institute of Electrical and Electronics Engineers (IEEE) Standard 802.11) network or a Bluetooth (IEEE Standard 802.15.1) personal area network). In this manner, the computers 304 and the client devices 310 may communicate over various types of transmission mediums.

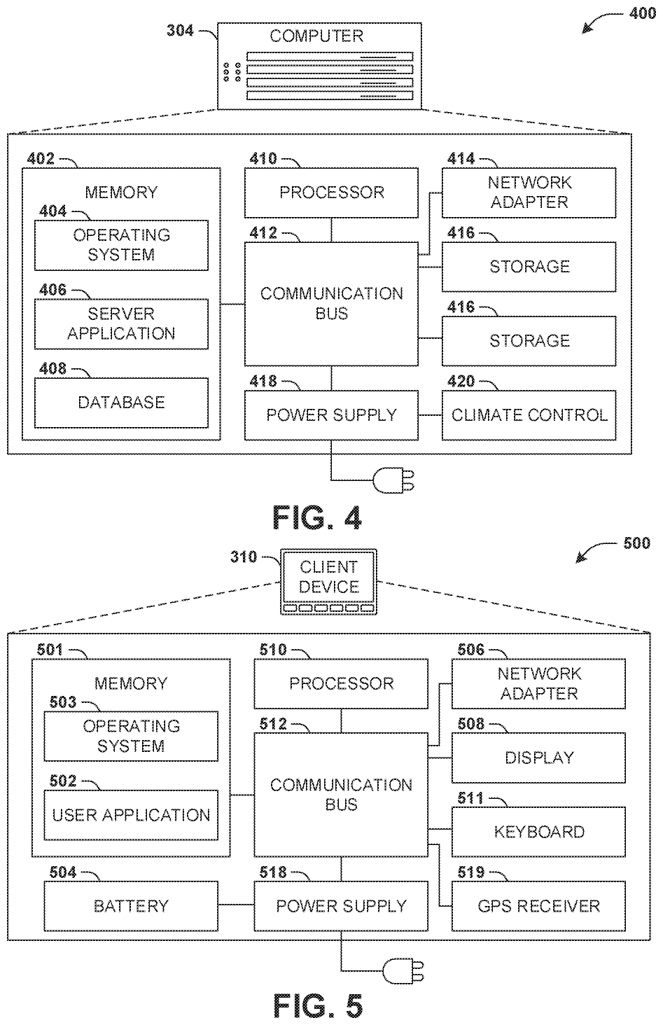

FIG. 4 presents a schematic architecture diagram 400 of a computer 304 that may utilize at least a portion of the techniques provided herein. Such a computer 304 may vary widely in configuration or capabilities, alone or in conjunction with other computers, in order to provide a service such as the service 302.

The computer 304 may comprise one or more processors 410 that process instructions. The one or more processors 410 may optionally include a plurality of cores; one or more coprocessors, such as a mathematics coprocessor or an integrated graphical processing unit (GPU); and/or one or more layers of local cache memory. The computer 304 may comprise memory 402 storing various forms of applications, such as an operating system 404; one or more computer applications 406; and/or various forms of data, such as a database 408 or a file system. The computer 304 may comprise a variety of peripheral components, such as a wired and/or wireless network adapter 414 connectible to a local area network and/or wide area network; one or more storage components 416, such as a hard disk drive, a solid-state storage device (SSD), a flash memory device, and/or a magnetic and/or optical disk reader.

The computer 304 may comprise a mainboard featuring one or more communication buses 412 that interconnect the processor 410, the memory 402, and various peripherals, using a variety of bus technologies, such as a variant of a serial or parallel AT Attachment (ATA) bus protocol; a Uniform Serial Bus (USB) protocol; and/or Small Computer System Interface (SCI) bus protocol. In a multibus scenario, a communication bus 412 may interconnect the computer 304 with at least one other computer. Other components that may optionally be included with the computer 304 (though not shown in the schematic architecture diagram 400 of FIG. 4) include a display; a display adapter, such as a graphical processing unit (GPU); input peripherals, such as a keyboard and/or mouse; and a flash memory device that may store a basic input/output system (BIOS) routine that facilitates booting the computer 304 to a state of readiness.

The computer 304 may operate in various physical enclosures, such as a desktop or tower, and/or may be integrated with a display as an “all-in-one” device. The computer 304 may be mounted horizontally and/or in a cabinet or rack, and/or may simply comprise an interconnected set of components. The computer 304 may comprise a dedicated and/or shared power supply 418 that supplies and/or regulates power for the other components. The computer 304 may provide power to and/or receive power from another computer and/or other devices. The computer 304 may comprise a shared and/or dedicated climate control unit 420 that regulates climate properties, such as temperature, humidity, and/or airflow. Many such computers 304 may be configured and/or adapted to utilize at least a portion of the techniques presented herein.

FIG. 5 presents a schematic architecture diagram 500 of a client device 310 whereupon at least a portion of the techniques presented herein may be implemented. Such a client device 310 may vary widely in configuration or capabilities, in order to provide a variety of functionality to a user such as the user 312. The client device 310 may be provided in a variety of form factors, such as a desktop or tower workstation; an “all-in-one” device integrated with a display 508; a laptop, tablet, convertible tablet, or palmtop device; a wearable device mountable in a headset, eyeglass, earpiece, and/or wristwatch, and/or integrated with an article of clothing; and/or a component of a piece of furniture, such as a tabletop, and/or of another device, such as a vehicle or residence. The client device 310 may serve the user in a variety of roles, such as a workstation, kiosk, media player, gaming device, and/or appliance.

The client device 310 may comprise one or more processors 510 that process instructions. The one or more processors 510 may optionally include a plurality of cores; one or more coprocessors, such as a mathematics coprocessor or an integrated graphical processing unit (GPU); and/or one or more layers of local cache memory. The client device 310 may comprise memory 501 storing various forms of applications, such as an operating system 503; one or more user applications 502, such as document applications, media applications, file and/or data access applications, communication applications such as web browsers and/or email clients, utilities, and/or games; and/or drivers for various peripherals. The client device 310 may comprise a variety of peripheral components, such as a wired and/or wireless network adapter 506 connectible to a local area network and/or wide area network; one or more output components, such as a display 508 coupled with a display adapter (optionally including a graphical processing unit (GPU)), a sound adapter coupled with a speaker, and/or a printer; input devices for receiving input from the user, such as a keyboard 511, a mouse, a microphone, a camera, and/or a touch-sensitive component of the display 508; and/or environmental sensors, such as a global positioning system (GPS) receiver 519 that detects the location, velocity, and/or acceleration of the client device 310, a compass, accelerometer, and/or gyroscope that detects a physical orientation of the client device 310. Other components that may optionally be included with the client device 310 (though not shown in the schematic architecture diagram 500 of FIG. 5) include one or more storage components, such as a hard disk drive, a solid-state storage device (SSD), a flash memory device, and/or a magnetic and/or optical disk reader; and/or a flash memory device that may store a basic input/output system (BIOS) routine that facilitates booting the client device 310 to a state of readiness; and a climate control unit that regulates climate properties, such as temperature, humidity, and airflow.

The client device 310 may comprise a mainboard featuring one or more communication buses 512 that interconnect the processor 510, the memory 501, and various peripherals, using a variety of bus technologies, such as a variant of a serial or parallel AT Attachment (ATA) bus protocol; the Uniform Serial Bus (USB) protocol; and/or the Small Computer System Interface (SCI) bus protocol. The client device 310 may comprise a dedicated and/or shared power supply 518 that supplies and/or regulates power for other components, and/or a battery 504 that stores power for use while the client device 310 is not connected to a power source via the power supply 518. The client device 310 may provide power to and/or receive power from other client devices.

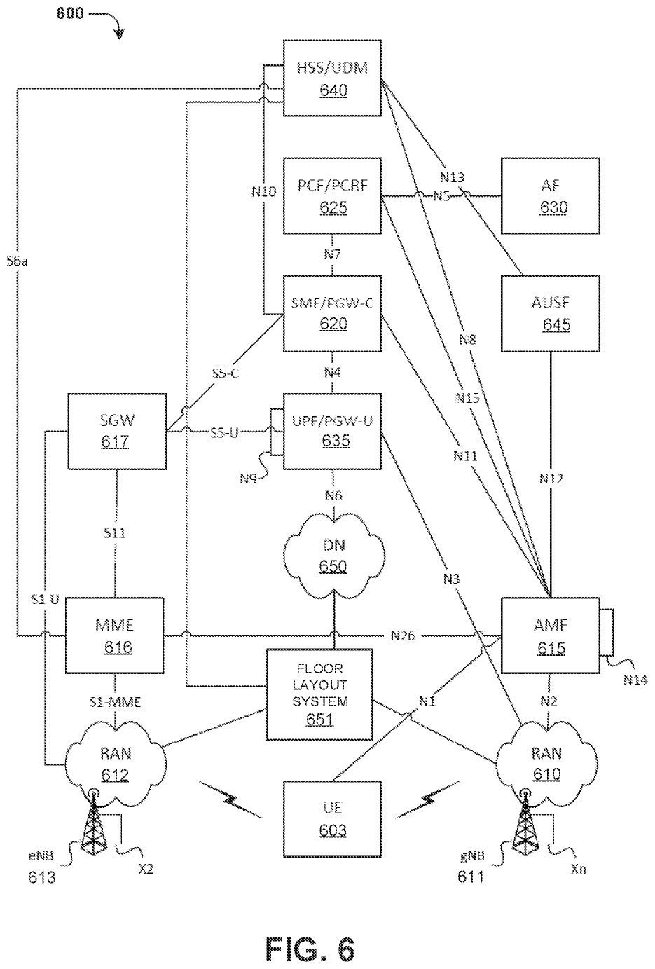

FIG. 6 illustrates an example environment 600, in which one or more embodiments may be implemented. In some embodiments, environment 600 may correspond to a Fifth Generation (“5G”) network, and/or may include elements of a 5G network. In some embodiments, environment 600 may correspond to a 5G Non-Standalone (“NSA”) architecture, in which a 5G radio access technology (“RAT”) may be used in conjunction with one or more other RATs (e.g., a Long-Term Evolution (“LTE”) RAT), and/or in which elements of a 5G core network may be implemented by, may be communicatively coupled with, and/or may include elements of another type of core network (e.g., an evolved packet core (“EPC”)). As shown, environment 600 may include UE 603, RAN 610 (which may include one or more Next Generation Node Bs (“gNBs”) 611), RAN 612 (which may include one or more one or more evolved Node Bs (“eNBs”) 613), and various network functions such as Access and Mobility Management Function (“AMF”) 615, Mobility Management Entity (“MME”) 616, Serving Gateway (“SGW”) 617, Session Management Function (“SMF”)/Packet Data Network (“PDN”) Gateway (“PGW”)-Control plane function (“PGW-C”) 620, Policy Control Function (“PCF”)/Policy Charging and Rules Function (“PCRF”) 625, Application Function (“AF”) 630, User Plane Function (“UPF”)/PGW-User plane function (“PGW-U”) 635, Home Subscriber Server (“HSS”)/Unified Data Management (“UDM”) 640, and Authentication Server Function (“AUSF”) 645. Environment 600 may also include one or more networks, such as Data Network (“DN”) 650. Environment 600 may include one or more additional devices or systems communicatively coupled to one or more networks (e.g., DN 650), such as floor layout system 651.

The example shown in FIG. 6 illustrates one instance of each network component or function (e.g., one instance of SMF/PGW-C 620, PCF/PCRF 625, UPF/PGW-U 635, HSS/UDM 640, and/or 645). In practice, environment 600 may include multiple instances of such components or functions. For example, in some embodiments, environment 600 may include multiple “slices” of a core network, where each slice includes a discrete set of network functions (e.g., one slice may include a first instance of SMF/PGW-C 620, PCF/PCRF 625, UPF/PGW-U 635, HSS/UDM 640, and/or 645, while another slice may include a second instance of SMF/PGW-C 620, PCF/PCRF 625, UPF/PGW-U 635, HSS/UDM 640, and/or 645). The different slices may provide differentiated levels of service, such as service in accordance with different Quality of Service (“QoS”) parameters.

The quantity of devices and/or networks, illustrated in FIG. 6, is provided for explanatory purposes only. In practice, environment 600 may include additional devices and/or networks, fewer devices and/or networks, different devices and/or networks, or differently arranged devices and/or networks than illustrated in FIG. 6. For example, while not shown, environment 600 may include devices that facilitate or enable communication between various components shown in environment 600, such as routers, modems, gateways, switches, hubs, etc. Alternatively and/or additionally, one or more of the devices of environment 600 may perform one or more network functions described as being performed by another one or more of the devices of environment 600. Devices of environment 600 may interconnect with each other and/or other devices via wired connections, wireless connections, or a combination of wired and wireless connections. In some implementations, one or more devices of environment 600 may be physically integrated in, and/or may be physically attached to, one or more other devices of environment 600.

UE 603 may include a computation and communication device, such as a wireless mobile communication device that is capable of communicating with RAN 610, RAN 612, and/or DN 650. UE 603 may be, or may include, a radiotelephone, a personal communications system (“PCS”) terminal (e.g., a device that combines a cellular radiotelephone with data processing and data communications capabilities), a personal digital assistant (“PDA”) (e.g., a device that may include a radiotelephone, a pager, Internet/intranet access, etc.), a smart phone, a laptop computer, a tablet computer, a camera, a personal gaming system, an IoT device (e.g., a sensor, a smart home appliance, or the like), a wearable device, an Internet of Things (“IoT”) device, a Mobile-to-Mobile (“M2M”) device, or another type of mobile computation and communication device. UE 603 may send traffic to and/or receive traffic (e.g., user plane traffic) from DN 650 via RAN 610, RAN 612, and/or UPF/PGW-U 635.

RAN 610 may be, or may include, a 5G RAN that includes one or more base stations (e.g., one or more gNBs 611), via which UE 603 may communicate with one or more other elements of environment 600. UE 603 may communicate with RAN 610 via an air interface (e.g., as provided by gNB 611). For instance, RAN 610 may receive traffic (e.g., voice call traffic, data traffic, messaging traffic, signaling traffic, etc.) from UE 603 via the air interface, and may communicate the traffic to UPF/PGW-U 635, and/or one or more other devices or networks. Similarly, RAN 610 may receive traffic intended for UE 603 (e.g., from UPF/PGW-U 635, AMF 615, and/or one or more other devices or networks) and may communicate the traffic to UE 603 via the air interface.

RAN 612 may be, or may include, a LTE RAN that includes one or more base stations (e.g., one or more eNBs 613), via which UE 603 may communicate with one or more other elements of environment 600. UE 603 may communicate with RAN 612 via an air interface (e.g., as provided by eNB 613). For instance, RAN 610 may receive traffic (e.g., voice call traffic, data traffic, messaging traffic, signaling traffic, etc.) from UE 603 via the air interface, and may communicate the traffic to UPF/PGW-U 635, and/or one or more other devices or networks. Similarly, RAN 610 may receive traffic intended for UE 603 (e.g., from UPF/PGW-U 635, SGW 617, and/or one or more other devices or networks) and may communicate the traffic to UE 603 via the air interface.

AMF 615 may include one or more devices, systems, Virtualized Network Functions (“VNFs”), etc., that perform operations to register UE 603 with the 5G network, to establish bearer channels associated with a session with UE 603, to hand off UE 603 from the 5G network to another network, to hand off UE 603 from the other network to the 5G network, manage mobility of UE 603 between RANs 610 and/or gNBs 611, and/or to perform other operations. In some embodiments, the 5G network may include multiple AMFs 615, which communicate with each other via the N14 interface (denoted in FIG. 6 by the line marked “N14” originating and terminating at AMF 615).

MME 616 may include one or more devices, systems, VNFs, etc., that perform operations to register UE 603 with the EPC, to establish bearer channels associated with a session with UE 603, to hand off UE 603 from the EPC to another network, to hand off UE 603 from another network to the EPC, manage mobility of UE 603 between RANs 612 and/or eNBs 613, and/or to perform other operations.

SGW 617 may include one or more devices, systems, VNFs, etc., that aggregate traffic received from one or more eNBs 613 and send the aggregated traffic to an external network or device via UPF/PGW-U 635. Additionally, SGW 617 may aggregate traffic received from one or more UPF/PGW-Us 635 and may send the aggregated traffic to one or more eNBs 613. SGW 617 may operate as an anchor for the user plane during inter-eNB handovers and as an anchor for mobility between different telecommunication networks or RANs (e.g., RANs 610 and 612).

SMF/PGW-C 620 may include one or more devices, systems, VNFs, etc., that gather, process, store, and/or provide information in a manner described herein. SMF/PGW-C 620 may, for example, facilitate in the establishment of communication sessions on behalf of UE 603. In some embodiments, the establishment of communications sessions may be performed in accordance with one or more policies provided by PCF/PCRF 625.

PCF/PCRF 625 may include one or more devices, systems, VNFs, etc., that aggregate information to and from the 5G network and/or other sources. PCF/PCRF 625 may receive information regarding policies and/or subscriptions from one or more sources, such as subscriber databases and/or from one or more users (such as, for example, an administrator associated with PCF/PCRF 625).

AF 630 may include one or more devices, systems, VNFs, etc., that receive, store, and/or provide information that may be used in determining parameters (e.g., quality of service parameters, charging parameters, or the like) for certain applications.

UPF/PGW-U 635 may include one or more devices, systems, VNFs, etc., that receive, store, and/or provide data (e.g., user plane data). For example, UPF/PGW-U 635 may receive user plane data (e.g., voice call traffic, data traffic, etc.), destined for UE 603, from DN 650, and may forward the user plane data toward UE 603 (e.g., via RAN 610, SMF/PGW-C 620, and/or one or more other devices). In some embodiments, multiple UPFs 635 may be deployed (e.g., in different geographical locations), and the delivery of content to UE 603 may be coordinated via the N9 interface (e.g., as denoted in FIG. 6 by the line marked “N9” originating and terminating at UPF/PGW-U 635). Similarly, UPF/PGW-U 635 may receive traffic from UE 603 (e.g., via RAN 610, SMF/PGW-C 620, and/or one or more other devices), and may forward the traffic toward DN 650. In some embodiments, UPF/PGW-U 635 may communicate (e.g., via the N4 interface) with SMF/PGW-C 620, regarding user plane data processed by UPF/PGW-U 635.

HSS/UDM 640 and AUSF 645 may include one or more devices, systems, VNFs, etc., that manage, update, and/or store, in one or more memory devices associated with AUSF 645 and/or HSS/UDM 640, profile information associated with a subscriber. AUSF 645 and/or HSS/UDM 640 may perform authentication, authorization, and/or accounting operations associated with the subscriber and/or a communication session with UE 603.

DN 650 may include one or more wired and/or wireless networks. For example, DN 650 may include an Internet Protocol (“IP”)-based PDN, a wide area network (“WAN”) such as the Internet, a private enterprise network, and/or one or more other networks. UE 603 may communicate, through DN 650, with data servers, other UEs UE 603, and/or to other servers or applications that are coupled to DN 650. DN 650 may be connected to one or more other networks, such as a public switched telephone network (“PSTN”), a public land mobile network (“PLMN”), and/or another network. DN 650 may be connected to one or more devices, such as content providers, applications, web servers, and/or other devices, with which UE 603 may communicate.

The floor layout system 651 may include one or more devices, systems, VNFs, etc., that perform one or more operations described herein. For example, the floor layout system 651 may receive one or more unit locations (e.g., one or more locations of the plurality of locations 112) from one or more devices (e.g., at least one of a device 102, an engagement management device 104, a technician device 106, an agent device 108, a unit location system 110, etc.). Alternatively and/or additionally, the floor layout system 651 may generate a building profile associated with a building based upon the one or more unit locations. Alternatively and/or additionally, the floor layout system 651 may generate a floor layout associated with the building using a machine learning model and/or a floor layout generation module. Alternatively and/or additionally, the floor layout system 651 may receive an address indicative of a unit number associated with the building and/or determine, based upon the unit number, a location associated with the unit number using the floor layout. Alternatively and/or additionally, the floor layout system 651 may determine whether a unit associated with the unit number is within coverage of a service based upon the location. Alternatively and/or additionally, the floor layout system 651 may transmit an indication of whether the first unit is within coverage of the service to one or more devices, such as at least one of the UE 603 (e.g., the first client device 100) and/or to one or more devices associated with installing one or more components associated with the second service and/or activating the second service. Alternatively and/or additionally, the floor layout system 651 may provide service information via an interface, such as an API and/or a GUI to allow for information display.

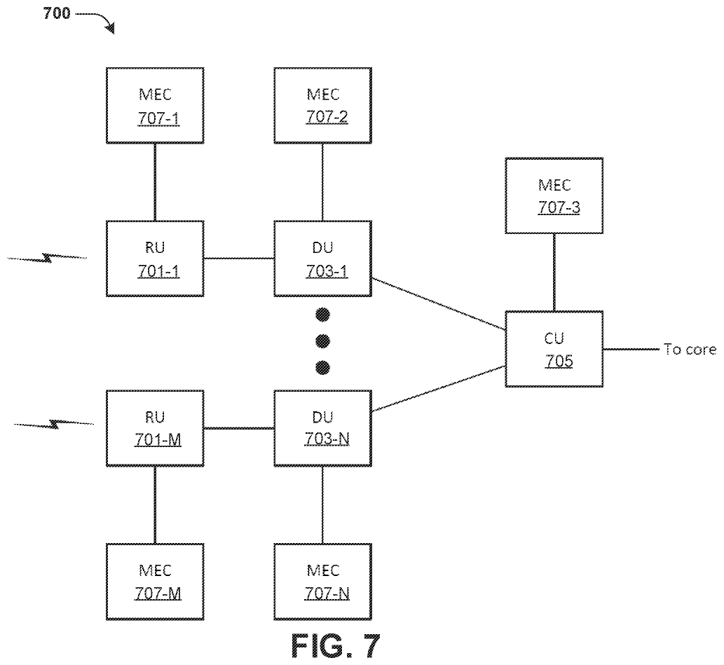

FIG. 7 illustrates an example Distributed Unit (“DU”) network 700, which may be included in and/or implemented by one or more RANs (e.g., RAN 610, RAN 612, or some other RAN). In some embodiments, a particular RAN may include one DU network 700. In some embodiments, a particular RAN may include multiple DU networks 700. In some embodiments, DU network 700 may correspond to a particular gNB 611 of a 5G RAN (e.g., RAN 610). In some embodiments, DU network 700 may correspond to multiple gNBs 611. In some embodiments, DU network 700 may correspond to one or more other types of base stations of one or more other types of RANs. As shown, DU network 700 may include Central Unit (“CU”) 705, one or more Distributed Units (“DUs”) 703-1 through 703-N (referred to individually as “DU 703,” or collectively as “DUs 703”), and one or more Radio Units (“RUs”) 701-1 through 701-M (referred to individually as “RU 701,” or collectively as “RUs 701”).

CU 705 may communicate with a core of a wireless network (e.g., may communicate with one or more of the devices or systems described above with respect to FIG. 6, such as AMF 615 and/or UPF/PGW-U 635). In the uplink direction (e.g., for traffic from UEs UE 603 to a core network), CU 705 may aggregate traffic from DUs 703, and forward the aggregated traffic to the core network. In some embodiments, CU 705 may receive traffic according to a given protocol (e.g., Radio Link Control (“RLC”)) from DUs 703, and may perform higher-layer processing (e.g., may aggregate/process RLC packets and generate Packet Data Convergence Protocol (“PDCP”) packets based upon the RLC packets) on the traffic received from DUs 703.

In accordance with some embodiments, CU 705 may receive downlink traffic (e.g., traffic from the core network) for a particular UE 603, and may determine which DU(s) 703 should receive the downlink traffic. DU 703 may include one or more devices that transmit traffic between a core network (e.g., via CU 705) and UE 603 (e.g., via a respective RU 701). DU 703 may, for example, receive traffic from RU 701 at a first layer (e.g., physical (“PHY”) layer traffic, or lower PHY layer traffic), and may process/aggregate the traffic to a second layer (e.g., upper PHY and/or RLC). DU 703 may receive traffic from CU 705 at the second layer, may process the traffic to the first layer, and provide the processed traffic to a respective RU 701 for transmission to UE 603.

RU 701 may include hardware circuitry (e.g., one or more RF transceivers, antennas, radios, and/or other suitable hardware) to communicate wirelessly (e.g., via an RF interface) with one or more UEs UE 603, one or more other DUs 703 (e.g., via RUs 701 associated with DUs 703), and/or any other suitable type of device. In the uplink direction, RU 701 may receive traffic from UE 603 and/or another DU 703 via the RF interface and may provide the traffic to DU 703. In the downlink direction, RU 701 may receive traffic from DU 703, and may provide the traffic to UE 603 and/or another DU 703.

RUs 701 may, in some embodiments, be communicatively coupled to one or more Multi-Access/Mobile Edge Computing (“MEC”) devices, referred to sometimes herein simply as (“MECs”) 707. For example, RU 701-1 may be communicatively coupled to MEC 707-1, RU 701-M may be communicatively coupled to MEC 707-M, DU 703-1 may be communicatively coupled to MEC 707-2, DU 703-N may be communicatively coupled to MEC 707-N, CU 705 may be communicatively coupled to MEC 707-3, and so on. MECs 707 may include hardware resources (e.g., configurable or provisionable hardware resources) that may be configured to provide services and/or otherwise process traffic to and/or from UE 603, via a respective RU 701.

For example, RU 701-1 may route some traffic, from UE 603, to MEC 707-1 instead of to a core network (e.g., via DU 703 and CU 705). MEC 707-1 may process the traffic, perform one or more computations based upon the received traffic, and may provide traffic to UE 603 via RU 701-1. In this manner, ultra-low latency services may be provided to UE 603, as traffic does not need to traverse DU 703, CU 705, and an intervening backhaul network between DU network 700 and the core network. In some embodiments, MEC 707 may include, and/or may implement some or all of the functionality described above with respect to at least one of the floor layout system 651, the floor layout system 114, the first client device 100, etc.

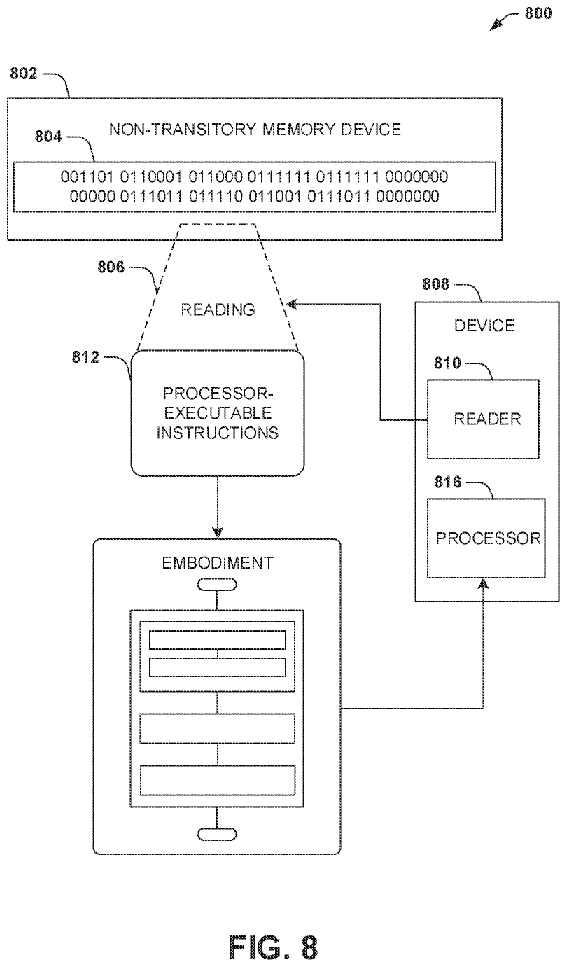

FIG. 8 is an illustration of a scenario 800 involving an example non-transitory machine readable medium 802. The non-transitory machine readable medium 802 may comprise processor-executable instructions 812 that when executed by a processor 816 cause performance (e.g., by the processor 816) of at least some of the provisions herein. The non-transitory machine readable medium 802 may comprise a memory semiconductor (e.g., a semiconductor utilizing static random access memory (SRAM), dynamic random access memory (DRAM), and/or synchronous dynamic random access memory (SDRAM) technologies), a platter of a hard disk drive, a flash memory device, or a magnetic or optical disc (such as a compact disk (CD), a digital versatile disk (DVD), or floppy disk). The example non-transitory machine readable medium 802 stores computer-readable data 804 that, when subjected to reading 806 by a reader 810 of a device 808 (e.g., a read head of a hard disk drive, or a read operation invoked on a solid-state storage device), express the processor-executable instructions 812. In some embodiments, the processor-executable instructions 812, when executed cause performance of operations, such as at least some of the example method 200 of FIG. 2, for example. In some embodiments, the processor-executable instructions 812 are configured to cause implementation of a system, such as at least some of the example system 101 of FIGS. 1A-1J, for example.

To the extent the aforementioned implementations collect, store, or employ personal information of individuals, groups or other entities, it should be understood that such information shall be used in accordance with all applicable laws concerning protection of personal information. Additionally, the collection, storage, and use of such information can be subject to consent of the individual to such activity, for example, through well known “opt-in” or “opt-out” processes as can be appropriate for the situation and type of information. Storage and use of personal information can be in an appropriately secure manner reflective of the type of information, for example, through various access control, encryption and anonymization techniques for particularly sensitive information.

As used in this application, “component,” “module,” “system”, “interface”, and/or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless specified otherwise, “first,” “second,” and/or the like are not intended to imply a temporal aspect, a spatial aspect, an ordering, etc. Rather, such terms are merely used as identifiers, names, etc. for features, elements, items, etc. For example, a first object and a second object generally correspond to object A and object B or two different or two identical objects or the same object.

Moreover, “example” is used herein to mean serving as an example, instance, illustration, etc., and not necessarily as advantageous. As used herein, “or” is intended to mean an inclusive “or” rather than an exclusive “or”. In addition, “a” and “an” as used in this application are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, and/or variants thereof are used in either the detailed description or the claims, such terms are intended to be inclusive in a manner similar to the term “comprising”.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing at least some of the claims.

Furthermore, the claimed subject matter may be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, carrier, or media. Of course, many modifications may be made to this configuration without departing from the scope or spirit of the claimed subject matter.

Various operations of embodiments are provided herein. In an embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering may be implemented without departing from the scope of the disclosure. Further, it will be understood that not all operations are necessarily present in each embodiment provided herein. Also, it will be understood that not all operations are necessary in some embodiments.

Also, although the disclosure has been shown and described with respect to one or more implementations, alterations and modifications may be made thereto and additional embodiments may be implemented based upon a reading and understanding of this specification and the annexed drawings. The disclosure includes all such modifications, alterations and additional embodiments and is limited only by the scope of the following claims. The specification and drawings are accordingly to be regarded in an illustrative rather than restrictive sense. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method comprising:
identifying a plurality of sets of building information associated with a plurality of buildings, wherein a first set of building information of the plurality of sets of building information is indicative of unit layout information associated with a first building of the plurality of buildings;
training a machine learning model using the plurality of sets of building information to generate a trained machine learning model;
generating a building profile associated with a second building, wherein the building profile is indicative of:
geographical boundaries associated with the second building; and
one or more locations associated with one or more units in the second building;
determining, using the trained machine learning model, a unit number configuration associated with the second building based upon the building profile; and
generating, based upon the unit number configuration, a first floor layout associated with the second building, wherein the first floor layout is indicative of:
a first arrangement of first units in the second building; and
first unit numbers associated with the first units.

2. The method of claim 1, comprising:
receiving a unit number of a unit in the second building; and
determining, based upon the first floor layout, a location of the unit.

3. The method of claim 2, comprising:
determining, based upon the location of the unit, whether the unit is within coverage of a service.

4. The method of claim 1, comprising:
receiving the one or more locations from one or more client devices.

5. The method of claim 1, wherein:
the first set of building information of the plurality of sets of building information is indicative of a building shape associated with the first building.

6. The method of claim 5, comprising:
determining, using the trained machine learning model, building shape information associated with the second building based upon the building profile, wherein the generating the first floor layout is performed based upon the building shape information.

7. The method of claim 6, comprising:
determining, using the trained machine learning model, a confidence score of the building shape information, wherein the generating the first floor layout based upon the building shape information is performed based upon a determination that the confidence score exceeds a threshold confidence score.

8. The method of claim 1, comprising:
determining, using the trained machine learning model, a unit spacing parameter associated with the second building based upon the building profile, wherein the generating the first floor layout is performed based upon the unit spacing parameter.

9. The method of claim 8, comprising:
determining, using the trained machine learning model, a confidence score of the unit spacing parameter, wherein the generating the first floor layout based upon the unit spacing parameter is performed based upon a determination that the confidence score exceeds a threshold confidence score.

10. The method of claim 1, comprising:
determining, using the trained machine learning model, a confidence score of the unit number configuration, wherein the generating the first floor layout based upon the unit number configuration is performed based upon a determination that the confidence score exceeds a threshold confidence score.

11. The method of claim 1, wherein:
the first arrangement of the first units is indicative of first locations of the first units.

12. The method of claim 1, wherein:
the geographical boundaries of the building profile comprise geographical boundaries of a section of the second building; and
the first units are in the section of the second building.

13. A non-transitory computer-readable medium storing instructions that when executed perform operations comprising:
identifying a plurality of sets of building information associated with a plurality of buildings, wherein a first set of building information of the plurality of sets of building information is indicative of unit layout information associated with a first building of the plurality of buildings;
training a machine learning model using the plurality of sets of building information to generate a trained machine learning model;
generating a building profile associated with a section of a second building, wherein the building profile is indicative of:
geographical boundaries of the section of the second building; and
one or more locations associated with one or more units in the section of the second building;
determining, using the trained machine learning model, a unit number configuration associated with the section of the second building based upon the building profile; and
generating, based upon the unit number configuration, a first floor layout associated with the section of the second building, wherein the first floor layout is indicative of:
a first arrangement of first units in the section of the second building; and
first unit numbers associated with the first units.

14. The non-transitory computer-readable medium of claim 13, the operations comprising:
receiving a unit number of a unit in the section of the second building; and
determining, based upon the first floor layout, a location of the unit.

15. The non-transitory computer-readable medium of claim 14, the operations comprising:
determining, based upon the location of the unit, whether the unit is within coverage of a service.

16. The non-transitory computer-readable medium of claim 13, wherein:
the first set of building information of the plurality of sets of building information is indicative of a building shape associated with the first building.

17. The non-transitory computer-readable medium of claim 16, the operations comprising:
determining, using the trained machine learning model, building shape information associated with the section of the second building based upon the building profile, wherein the generating the first floor layout is performed based upon the building shape information.

18. The non-transitory computer-readable medium of claim 17, the operations comprising:
determining, using the trained machine learning model, a confidence score of the building shape information, wherein the generating the first floor layout based upon the building shape information is performed based upon a determination that the confidence score exceeds a threshold confidence score.

19. A device comprising:
a processor coupled to memory, the processor configured to execute instructions to perform operations comprising:
identifying a plurality of sets of building information associated with a plurality of buildings, wherein a first set of building information of the plurality of sets of building information is indicative of unit layout information associated with a first building of the plurality of buildings;
training a machine learning model using the plurality of sets of building information to generate a trained machine learning model;
generating a building profile associated with a second building, wherein the building profile is indicative of:
geographical boundaries associated with the second building; and
one or more locations associated with one or more units in the second building;
determining, using the trained machine learning model, a unit number configuration associated with the second building based upon the building profile; and
generating, based upon the unit number configuration, a first floor layout associated with the second building, wherein the first floor layout is indicative of:
a first arrangement of first units in the second building; and
first unit numbers associated with the first units.

20. The device of claim 19, the operations comprising:
determining, based upon the first floor layout, a location of a unit in the second building; and
determining, based upon the location of the unit, whether the unit is within coverage of a service.
